(19) United States
(12) Patent Application Publication
(10) Pub. No.: US 2026/0251977 A1
(43) Pub. Date: Aug. 27, 2026

(54) COMPOSITION AND METHOD FOR MANUFACTURING SEMICONDUCTOR SUBSTRATE

(71) Applicant: JSR CORPORATION, Tokyo (JP)

(72) Inventors: Masato DOBASHI, Tokyo (JP); Satoshi DEI, Tokyo (JP); Kengo EHARA, Tokyo (JP); Shunpei AKITA, Tokyo (JP); Yuya HAYASHI, Tokyo (JP); Yukihiro HAYASHI, Tokyo (JP); Tatsuya KASAI, Tokyo (JP); Tomoharu KAWAZU, Tokyo (JP); Kazuya TAKADA, Tokyo (JP)

(73) Assignee: JSR CORPORATION, Tokyo (JP)

(21) Appl. No.: 19/643,002

(22) Filed: Apr. 9, 2026

Related U.S. Application Data
(63) Continuation-in-part of application No. PCT/JP2024/033501, filed on Sep. 19, 2024.

(30) Foreign Application Priority Data
Oct. 13, 2023 (JP) 2023-177313

(51) Int. Cl. G03F 7/11; G03F 7/20; H10P 50/00; H10P 76/20

(52) U.S. Cl. CPC G03F 7/11; G03F 7/2004; H10P 50/692; H10P 50/695; H10P 76/2041

(57) ABSTRACT

A composition includes a polymer including a repeating unit represented by formula (1); and a solvent. R¹ is a hydrogen atom or a substituted or unsubstituted monovalent hydrocarbon group having 1 to 20 carbon atoms; L¹ is a (1+n)-valent linking group; Ar¹ is a monovalent group including an aromatic ring having 6 to 20 ring members, the aromatic ring including at least one halogen atom; n is an integer of 1 to 3; and L¹ includes at least one group (A) selected from the group consisting of groups represented by formula (2-1) to formula (2-8).

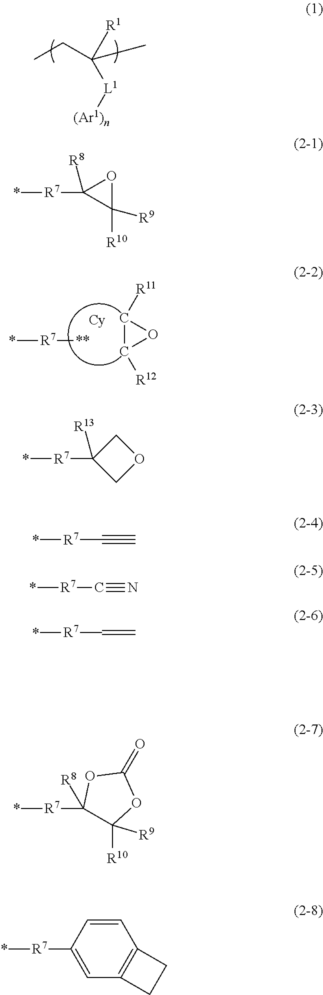

### CROSS-REFERENCE TO RELATED APPLICATIONS

The present application is a continuation-in-part application of International Patent Application No. PCT/JP2024/033501 filed Sep. 19, 2024, which claims priority to Japanese Patent Application No. 2023-177313 filed Oct. 13, 2023. The contents of these applications are incorporated herein by reference in their entirety.

### BACKGROUND OF THE DISCLOSURE

### Technical Field

The present disclosure relates to a method for manufacturing a semiconductor substrate and a composition.

### Background Art

A semiconductor device is produced using, for example, a multilayer resist process in which a resist pattern is formed by exposing and developing a resist film laminated on a substrate with a resist underlayer film, such as an organic underlayer film or a silicon-containing film, being interposed between them. In this process, the resist underlayer film is etched using this resist pattern as a mask, and the substrate is further etched using the obtained resist underlayer film pattern as a mask so that a desired pattern is formed on the semiconductor substrate.

In recent years, highly enhanced integration of semiconductor devices has further advanced, and exposure light to be used tends to have a shorter wavelength, as from a KrF excimer laser beam (248 nm) or an ArF excimer laser beam (193 nm) to an extreme ultraviolet ray (13.5 nm; hereinafter also referred to as “EUV”). Various studies have been conducted on compositions for forming a resist underlayer film (see WO 2013/141015 A).

### SUMMARY

According to an aspect of the present disclosure, a composition includes: a polymer including a repeating unit represented by formula (1) (hereinafter, also referred to as “polymer [A]”); and a solvent (hereinafter, also referred to as “solvent [B]”).

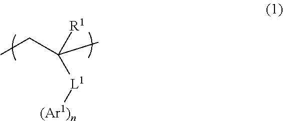

In the formula (1), R¹ is a hydrogen atom or a substituted or unsubstituted monovalent hydrocarbon group having 1 to 20 carbon atoms; L¹ is a (1+n)-valent linking group; Ar¹ is a monovalent group including an aromatic ring having 6 to 20 ring members, the aromatic ring including at least one halogen atom; n is an integer of 1 to 3; when n is 2 or more, a plurality of Ar¹s are same as or different from each other; and L¹ includes at least one group (A) selected from the group consisting of a group represented by formula (2-1), a group represented by formula (2-2), a group represented by formula (2-3), a group represented by formula (2-4), a group represented by formula (2-5), a group represented by formula (2-6), a group represented by formula (2-7), and a group represented by formula (2-8).

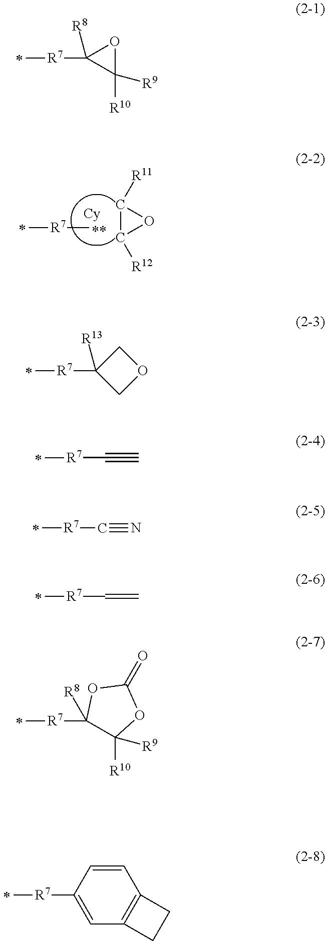

In the formulas (2-1) to (2-8), R⁷ is independently a divalent organic group having 1 to 20 carbon atoms or a single bond; R⁸, R⁹, R¹⁰, and R¹³ are each independently a hydrogen atom or a monovalent organic group having 1 to 20 carbon atoms; Cy is a ring structure having 3 to 20 ring members formed together with the two carbon atoms in the formula (2-2); R¹¹ is a hydrogen atom, a monovalent organic group having 1 to 20 carbon atoms, or a single bond; R¹² is a hydrogen atom or a monovalent organic group having 1 to 20 carbon atoms; ** is a bond to an atom constituting Cy, and when R¹¹ is a single bond, R¹¹ bonds to **; and * is a bond to an atom constituting L¹.

According to another aspect of the present disclosure, a method for producing a semiconductor substrate includes: applying a composition for forming a resist underlayer film directly or indirectly to a substrate to form a resist under layer film; applying a composition for forming a resist film to the resist underlayer film to form a resist film; exposing the resist film to radiation; and developing the exposed resist film. The composition for forming a resist underlayer film includes: a polymer including a repeating unit represented by formula (1); and a solvent.

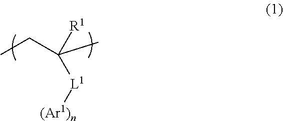

In the formula (1), R¹ is a hydrogen atom or a substituted or unsubstituted monovalent hydrocarbon group having 1 to 20 carbon atoms; L¹ is a (1+n)-valent linking group; Ar¹ is a monovalent group including an aromatic ring having 6 to 20 ring members, the aromatic ring including at least one halogen atom; n is an integer of 1 to 3; when n is 2 or more, a plurality of Ar¹s are same as or different from each other; and L¹ includes at least one group (A) selected from the group consisting of a group represented by formula (2-1), a group represented by formula (2-2), a group represented by formula (2-3), a group represented by formula (2-4), a group represented by formula (2-5), a group represented by formula (2-6), a group represented by formula (2-7), and a group represented by formula (2-8).

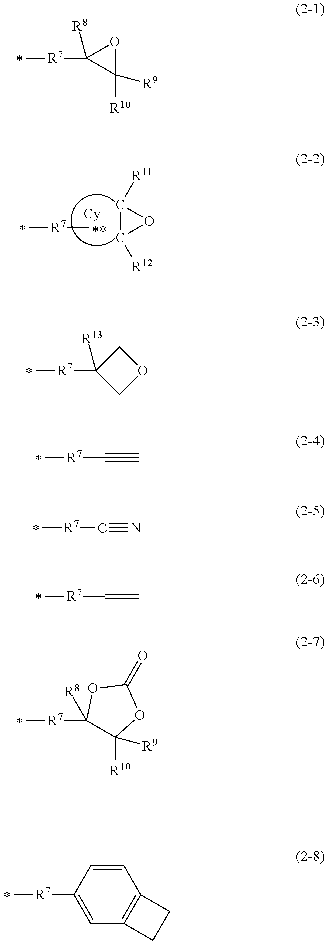

In the formulas (2-1) to (2-8), R⁷ is independently a divalent organic group having 1 to 20 carbon atoms or a single bond; R⁸, R⁹, R¹⁰, and R¹³ are each independently a hydrogen atom or a monovalent organic group having 1 to 20 carbon atoms; Cy is a ring structure having 3 to 20 ring members formed together with the two carbon atoms in the formula (2-2); R¹¹ is a hydrogen atom, a monovalent organic group having 1 to 20 carbon atoms, or a single bond; R¹² is a hydrogen atom or a monovalent organic group having 1 to 20 carbon atoms; ** is a bond to an atom constituting Cy, and when R¹¹ is a single bond, R¹¹ bonds to **; and * is a bond to an atom constituting L¹.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

Resist underlayer films are required to have solvent resistance to the solvent of a resist composition and resist pattern rectangularity of securing rectangularity of a resist pattern by inhibiting trailing of a pattern at a bottom part of a resist film.

When the composition for forming a resist underlayer film is used, a film excellent in solvent resistance and resist pattern rectangularity can be formed. According to the method for producing a semiconductor substrate, it is possible to efficiently produce a semiconductor substrate since a composition for forming a resist underlayer film capable of forming a resist underlayer film excellent in solvent resistance and resist pattern rectangularity is used. Therefore, these can be suitably used for the production of a semiconductor device, etc.

Hereinafter, a composition for forming a resist underlayer film and a method for producing a semiconductor substrate according to each embodiment of the present disclosure will be described in detail. Combinations of suitable modes in embodiments are also preferred.

### <<Composition for Forming Resist Underlayer Film>>

The composition for forming a resist underlayer film (hereinafter, also referred to as “composition”) contains a polymer [A] and a solvent [B]. The composition may contain any optional component as long as the effect of the present disclosure is not impaired.

The composition is suitable as a composition for forming an underlayer film of a resist film to be exposed to extreme ultraviolet rays. Examples of the composition for forming a resist film include a positive or negative chemically amplified resist composition containing a radiation-sensitive acid generator, a positive resist composition containing an alkali-soluble resin and a quinonediazide-based photosensitizer, a negative resist composition containing an alkali-soluble resin and a crosslinking agent, and a metal-containing resist composition containing a metal such as tin, zirconium, or hafnium. The underlayer film formed from the composition contains halogen atoms derived from the polymer [A], and therefore has a high efficiency in generating secondary electrons through absorption of extreme ultraviolet rays. As a result, when exposed to extreme ultraviolet rays, a sufficient difference in solubility occurs in the interface region of the organic resist film on the underlayer film side, or the insolubilization of the metal-containing resist film is promoted, thus trailing of the pattern at the bottom of the resist film can be suppressed and the rectangularity of the resist pattern can be secured. Since the polymer [A] has a specific group (A), a crosslinked structure is formed in the resulting resist underlayer film, and solubility in an organic solvent can be reduced. The lower limit of the content ratio of the metal or metal compound to the components other than the solvent in the metal-containing resist composition is preferably 50% by mass, more preferably 70% by mass, still more preferably 80% by mass, and particularly preferably 85% by mass. The upper limit of the content ratio is, for example, 100% by mass or 95% by mass.

Each component contained in the composition will be described below.

### <Polymer [A]>

The polymer [A] has a repeating unit represented by formula (1) (hereinafter, also referred to as “repeating unit (1)”). The polymer [A] can contain one type or two or more types of the repeating unit (1). The polymer [A] may have a repeating unit other than the repeating unit (1). The composition may contain one type or two or more types of the polymer [A].

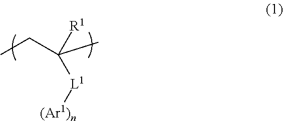

wherein, in the formula (1),
R¹ is a hydrogen atom or a substituted or unsubstituted monovalent hydrocarbon group having 1 to 20 carbon atoms,
L¹ is a single bond or a (1+n)-valent linking group, and
Ar¹ is a monovalent group having an aromatic ring having 6 to 20 ring members. The aromatic ring has at least one halogen atom. n is an integer of 1 to 3. When n is 2 or more, multiple Ar¹'s are the same or different. L¹ has at least one group (A) selected from the group consisting of a group represented by formula (2-1), a group represented by formula (2-2), a group represented by formula (2-3), a group represented by formula (2-4), a group represented by formula (2-5), a group represented by formula (2-6), a group represented by formula (2-7), and a group represented by formula (2-8),

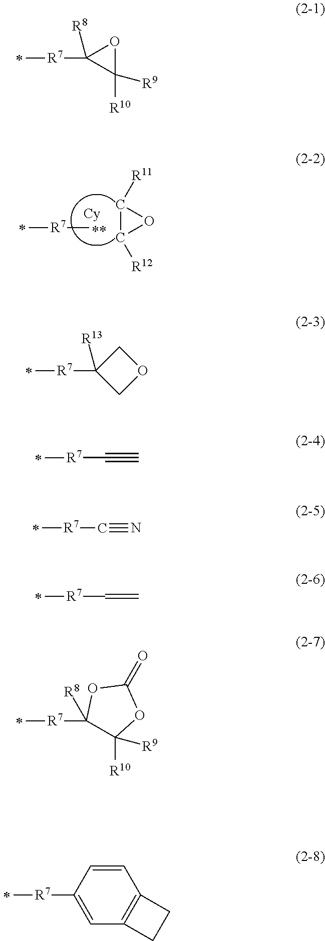

wherein, in the formula (2-1) to (2-8),
R⁷ is independently a divalent organic group having 1 to 20 carbon atoms or a single bond;
R⁸, R⁹, R¹⁰, and R¹³ are each independently a hydrogen atom or a monovalent organic group having 1 to 20 carbon atoms;
Cy is a ring structure having 3 to 20 ring members formed together with two carbon atoms in the formula (2-2); R¹¹ is a hydrogen atom, a monovalent organic group having 1 to 20 carbon atoms, or a single bond; R¹² is a hydrogen atom or a monovalent organic group having 1 to 20 carbon atoms; ** is a bond to an atom constituting Cy; and when R¹¹ is a single bond, R¹¹ bonds to **; and
* is a bond to an atom constituting L¹.

In the above formula (1), the monovalent hydrocarbon group having 1 to 20 carbon atoms represented by R¹ is not particularly limited, and examples thereof include a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and combinations thereof.

Examples of the monovalent chain hydrocarbon group having 1 to 20 carbon atoms include: alkyl groups such as a methyl group, an ethyl group, an n-propyl group, an i-propyl group, an n-butyl group, a sec-butyl group, a tert-butyl group, an n-pentyl group, an isopentyl group, and a neopentyl group; alkenyl groups such as an ethenyl group, a propenyl group, and a butenyl group; and alkynyl groups such as an ethynyl group, a propynyl group, and a butynyl group.

Examples of the monovalent alicyclic hydrocarbon group having 3 to 20 carbon atoms include cycloalkyl groups such as a cyclopentyl group and a cyclohexyl group; cycloalkenyl groups such as a cyclopropenyl group, a cyclopentenyl group, and a cyclohexenyl group; bridged cyclic saturated hydrocarbon groups such as a norbornyl group, an adamantyl group, and a tricyclodecyl group; and bridged cyclic unsaturated hydrocarbon groups such as a norbornenyl group and a tricyclodecenyl group.

Examples of the monovalent aromatic hydrocarbon group having 6 to 20 carbon atoms include a phenyl group, a tolyl group, a naphthyl group, an anthracenyl group, a pyrenyl group, a fluorenyl group, and a 9-methylidenefluorenyl group.

When R¹ has a substituent, examples of the substituent include monovalent chain hydrocarbon groups having 1 to 10 carbon atoms, halogen atoms such as a fluorine atom, a chlorine atom, a bromine atom, and an iodine atom, alkoxy groups such as a methoxy group, an ethoxy group, and a propoxy group, alkoxycarbonyl groups such as a methoxycarbonyl group and an ethoxycarbonyl group, alkoxycarbonyloxy groups such as a methoxycarbonyloxy group and an ethoxycarbonyloxy group, acyl groups such as a formyl group, an acetyl group, a propionyl group, and a butyryl group, a cyano group, a nitro group, and a hydroxy group.

Among them, a hydrogen atom or a methyl group is preferable as R¹ from the viewpoint of the copolymerizability of a monomer that affords the repeating unit (1).

In the above formula (1), examples of the divalent linking group represented by L¹ include a divalent hydrocarbon group having 1 to 20 carbon atoms, a divalent heteroatom-containing group, a group containing a divalent heteroatom-containing group between two carbon atoms of the foregoing divalent hydrocarbon group having 1 to 20 carbon atoms, a group obtained by substituting some or all of the hydrogen atoms of the foregoing hydrocarbon group with a monovalent heteroatom-containing group, and a combination thereof.

As the divalent hydrocarbon group having 1 to 20 carbon atoms, a group obtained by removing one hydrogen atom from the monovalent hydrocarbon group having 1 to 20 carbon atoms represented by R¹ can be suitably employed. The divalent hydrocarbon group having 1 to 20 carbon atoms is preferably an alkanediyl group having 1 to 10 carbon atoms, an arenediyl group having 6 to 10 carbon atoms, or combinations thereof.

Examples of the hetero atom that constitutes the divalent or monovalent hetero atom-containing group include an oxygen atom, a nitrogen atom, a sulfur atom, a phosphorus atom, a silicon atom, and halogen atoms. Examples of the halogen atoms include a fluorine atom, a chlorine atom, a bromine atom, and an iodine atom.

Examples of the divalent hetero atom-containing group include —CO—, —CS—, —NR′—, —O—, —S—, —SO₂—, and groups obtained by combining them. R¹ is a hydrogen atom or a hydrocarbon group having 1 to 10 carbon atoms. The divalent heteroatom-containing group is preferably —O—, —COO—, —NH—, or —S—.

Examples of the monovalent heteroatom-containing group include a hydroxy group, a sulfanyl group, a cyano group, a nitro group, a carboxy group, an amino group, and a halogen atom.

The divalent linking group represented by L¹ is preferably an alkanediyl group having 1 to 10 carbon atoms, a divalent heteroatom-containing group, an arenediyl group having 6 to 10 carbon atoms, or combinations thereof, and more preferably a combination of an alkanediyl group having 1 to 10 carbon atoms and a divalent heteroatom-containing group, or a combination of an alkanediyl group having 1 to 10 carbon atoms, a divalent heteroatom-containing group, and an arenediyl group having 6 to 10 carbon atoms.

In the above formulas (2-1) to (2-8), as the divalent organic group having 1 to 20 carbon atoms represented by R⁷, a divalent linking group represented by L¹ of the above formula (1) can be suitably employed.

As R⁷, a combination of a divalent hydrocarbon group having 1 to 10 carbon atoms and a divalent heteroatom-containing group is preferable, and a methanediyl group, an ethanediyl group, a propanediyl group, a benzenediyl group, or a combination thereof, and —O—, —CO—, or a combination thereof are more preferable.

In the above formulas (2-1) to (2-3), examples of the monovalent organic groups having 1 to 20 carbon atoms represented by R⁸, R⁹, R¹⁰, R¹¹, R¹², and R¹³ (hereinafter, also referred to as “R⁸ to R¹³”) include a monovalent hydrocarbon group having 1 to 20 carbon atoms, a group containing a divalent heteroatom-containing group between two carbon atoms of this hydrocarbon group or at the end of the hydrocarbon group, a group obtained by substituting some or all of the hydrogen atoms of the hydrocarbon group with a monovalent heteroatom-containing group, and a combination thereof. The “organic group” refers to a group having at least one carbon atom.

As the monovalent hydrocarbon group having 1 to 20 carbon atoms in R⁸ to R¹³, a monovalent hydrocarbon group having 1 to 20 carbon atoms represented by R¹ of the above formula (1) can be suitably employed.

As the divalent heteroatom-containing group and the monovalent heteroatom-containing group in R⁸ to R¹³, the divalent heteroatom-containing group and the monovalent heteroatom-containing group in L¹ of the above formula (1) can be suitably employed.

R⁸ to R¹³ are all preferably hydrogen atoms.

In the above formula (2-2), as the ring structure having 3 to 20 ring members, which is represented by Cy, formed together with two carbon atoms in the formula, a ring structure corresponding to a monovalent alicyclic hydrocarbon group having 3 to 20 carbon atoms in R¹ of the above formula (1) can be suitably employed. Cy is preferably a cycloalkane ring having 5 to 10 carbon atoms, and more preferably a cyclopentane ring, a cyclohexane ring, or a cycloheptane ring.

Specific examples of the group represented by the above formula (2-1) include structures represented by formulas (2-1-1) to (2-1-10).

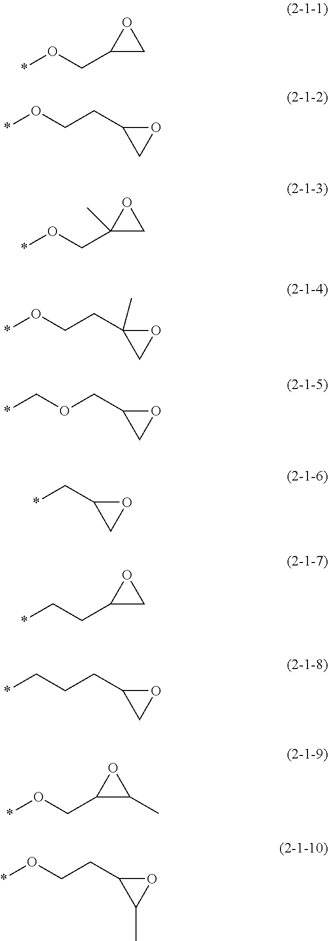

Specific examples of the group represented by the above formula (2-2) include structures represented by formulas (2-2-1) to (2-2-6).

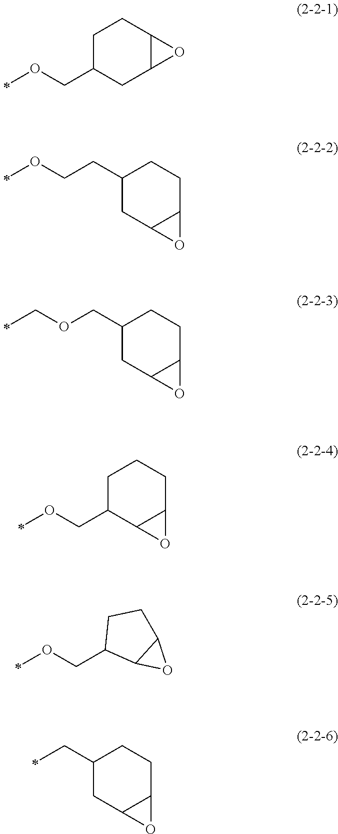

Specific examples of the group represented by the above formula (2-3) include structures represented by formulas (2-3-1) to (2-3-6).

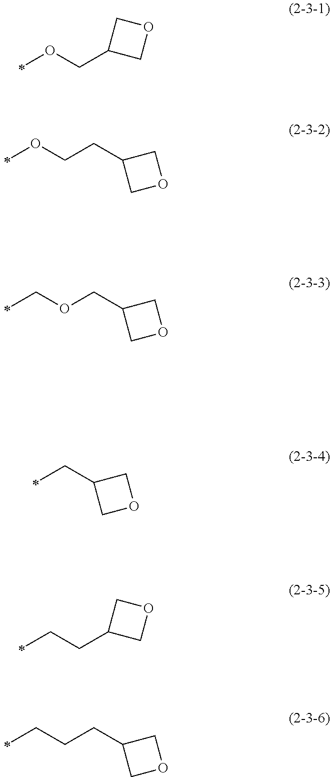

Specific examples of the group represented by the above formula (2-4) include structures represented by formulas (2-4-1) to (2-4-6).

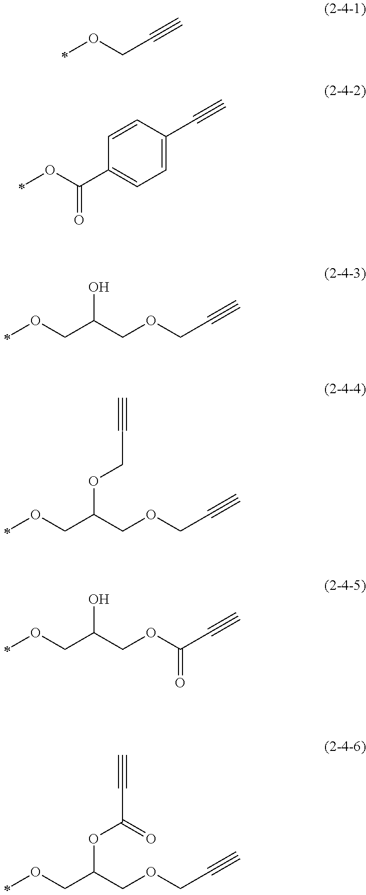

Specific examples of the group represented by the above formula (2-5) include structures represented by formulas (2-5-1) to (2-5-6).

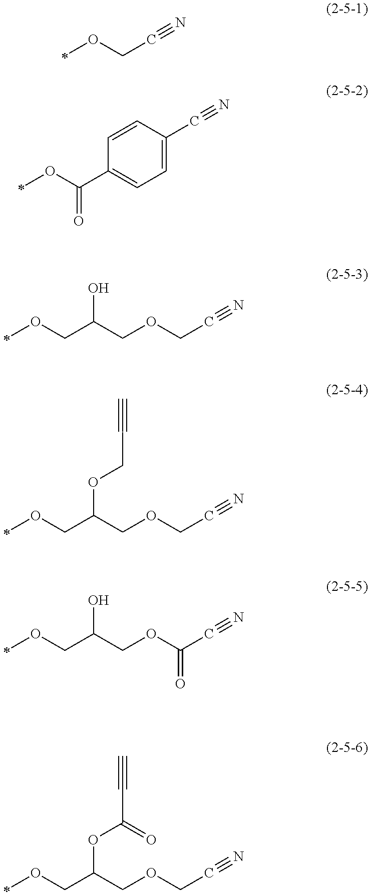

Specific examples of the group represented by the above formula (2-6) include structures represented by formulas (2-6-1) to (2-6-3).

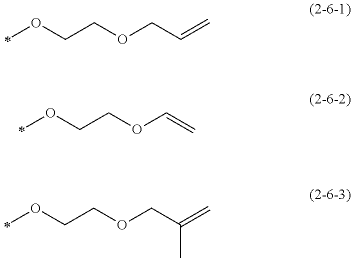

Specific examples of the group represented by the above formula (2-7) include structures represented by formulas (2-7-1) to (2-7-2).

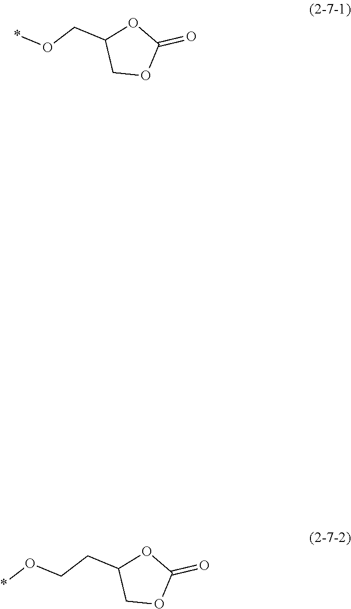 [SMILES: *OCC1COC(=O)O1 ; *OCCC1COC(=O)O1]

Specific examples of the group represented by the above formula (2-8) include structures represented by formulas (2-8-1) to (2-8-2).

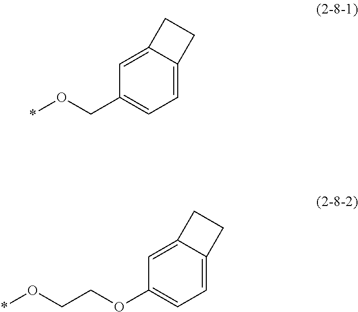

In the formula (1), L¹ is preferably represented by formula (3-1) or (3-2).

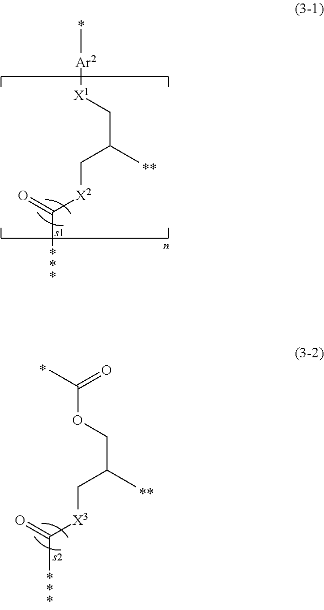

wherein, in the formula (3-1),
Ar² is a (1+n)-valent group having an aromatic ring having 6 to 20 ring members;
s1 is 0 or 1; and when there are a plurality of s1s, the plurality of s1s are same as or different from each other;
X¹ and X² are each independently —O—, —NH—, or —S—; when s1 is 1, X² is —O—; and when there are a plurality of X¹s and X²s, the plurality of X¹s and X²s are same as or different from each other;
n has a same definition as that in the formula (1);
wherein, in the formula (3-2),
s2 is 0 or 1;
X³ is —O—, —NH—, or —S—; when s2 is 1, X³ is —O—; and
wherein, in the formulas (3-1) and (3-2), * is a bond to a carbon atom to which R¹ bonds in the formula (1); ** is a bond to the group (A); and *** is a bond to Ar¹ in the formula (1).

In the above formula (3-1), examples of the aromatic ring having 6 to 20 ring members as Ar² include aromatic hydrocarbon rings such as a benzene ring, a naphthalene ring, an anthracene ring, an indene ring, and a pyrene ring, aromatic heterocyclic rings such as a pyridine ring, a pyrazine ring, a pyrimidine ring, a pyridazine ring, and a triazine ring, or a combination thereof. The aromatic ring of Ar² is preferably a benzene ring, a naphthalene ring, an anthracene ring, or a pyrene ring, more preferably a benzene ring or a naphthalene ring, and still more preferably a benzene ring.

As the (1+n)-valent group having an aromatic ring having 6 to 20 ring members represented by Ar², a group obtained by removing 1+n hydrogen atoms from the aromatic ring having 6 to 20 ring members can be suitably employed.

Ar² may have a substituent that can be possessed by R¹ of the above formula (1). When Ar² has a substituent, the substituent is preferably a halogen atom, and more preferably an iodine atom.

X¹ and X² are both preferably —O—.

n is preferably 1 or 2, and more preferably 1.

In the formula (3-2), X³ is preferably —O—.

In the above formula (1), as the aromatic ring having 6 to 20 ring members in Ar¹, the aromatic ring having 6 to 20 ring members in Ar² of the above formula (3-1) can be suitably employed.

The aromatic ring has at least one halogen atom. The aromatic ring may have two or three halogen atoms. In this case, the plurality of halogen atoms are same as or different from each other. Examples of the halogen atom include a fluorine atom, a chlorine atom, a bromine atom, and an iodine atom. The halogen atom is preferably an iodine atom.

Specific examples of the monomer that gives the repeating unit (1) include compounds represented by formulas (1-1) to (1-35).

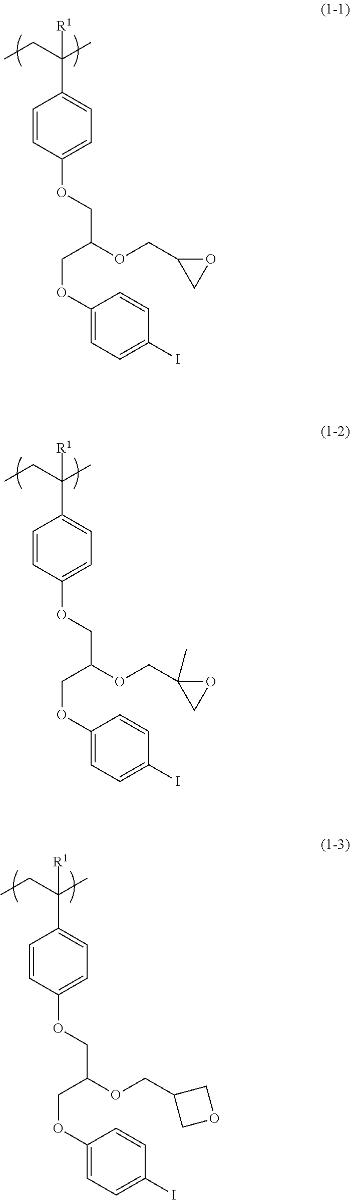

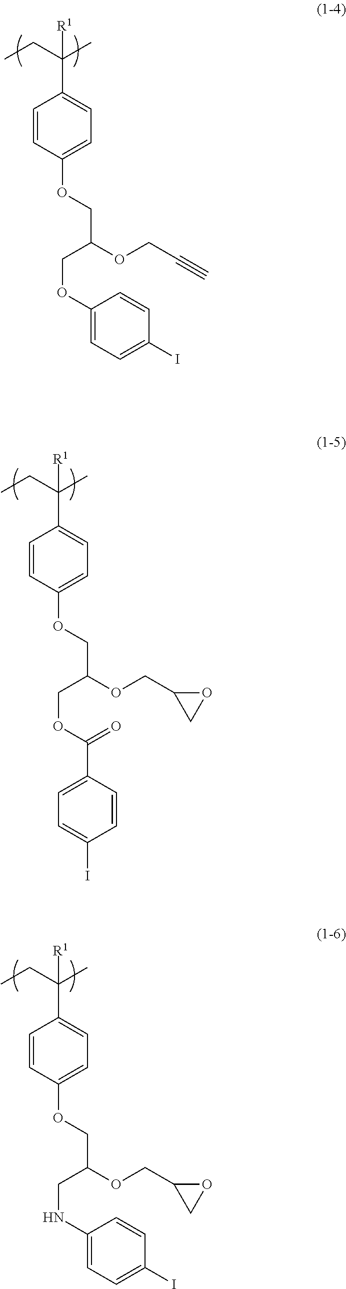

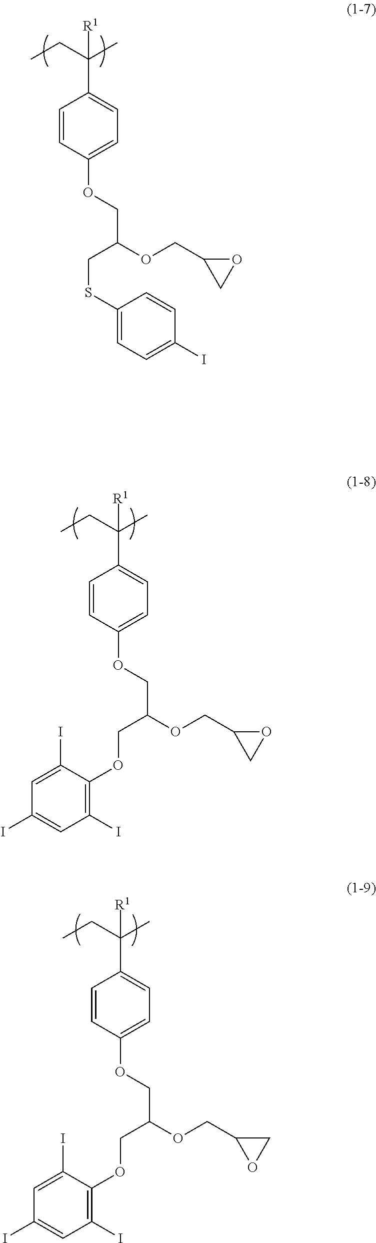

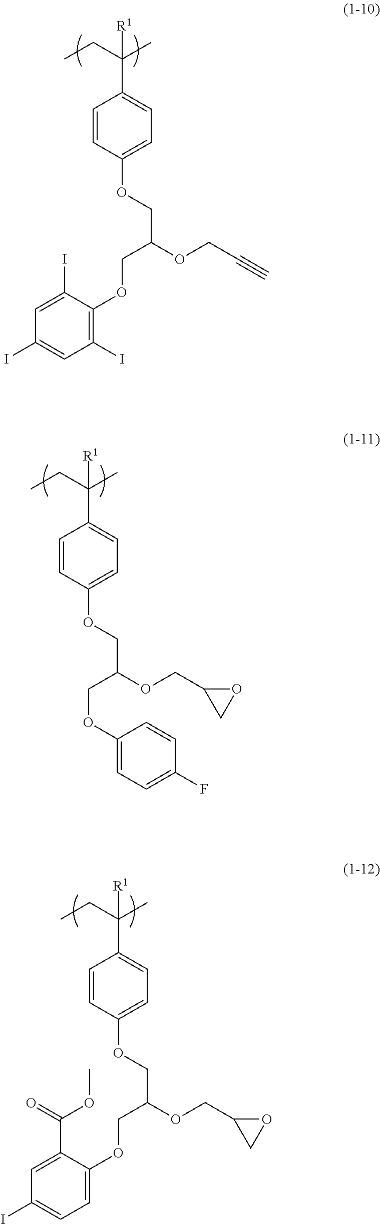

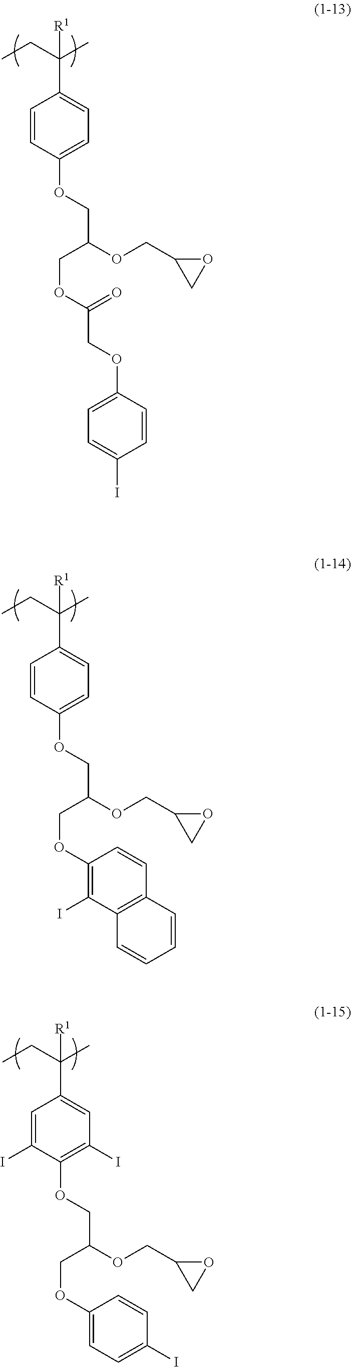

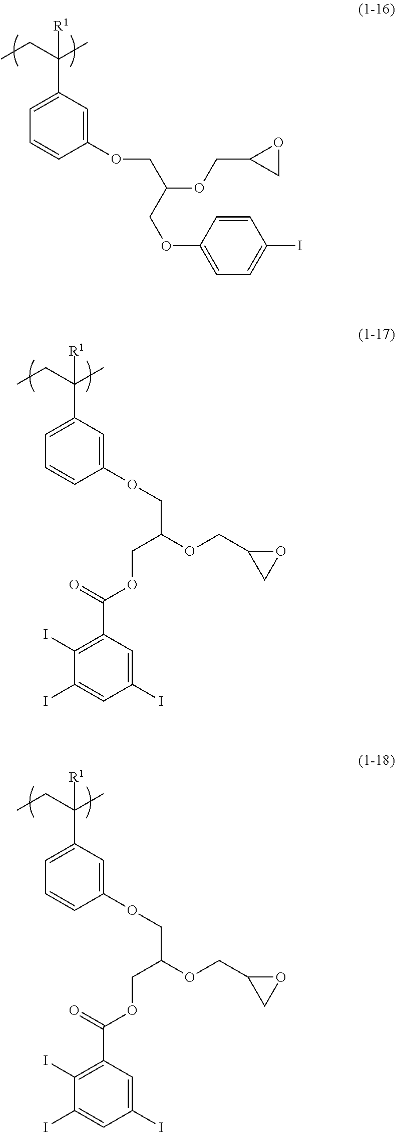

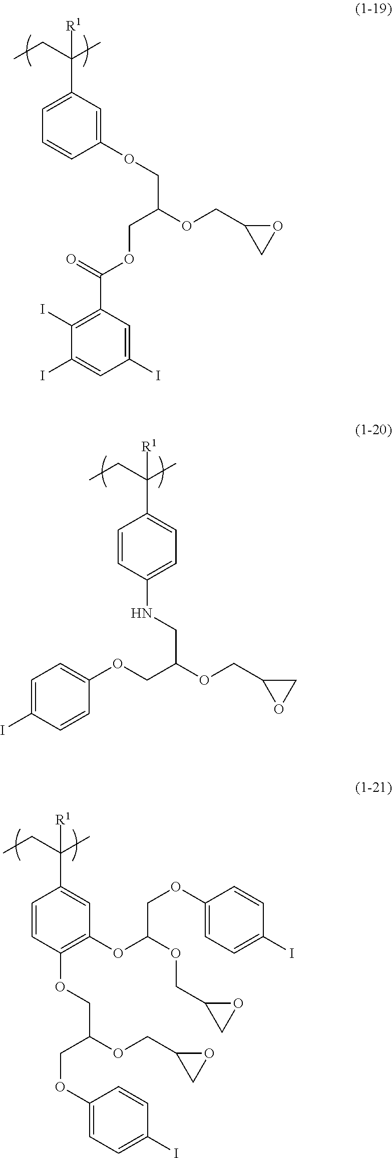

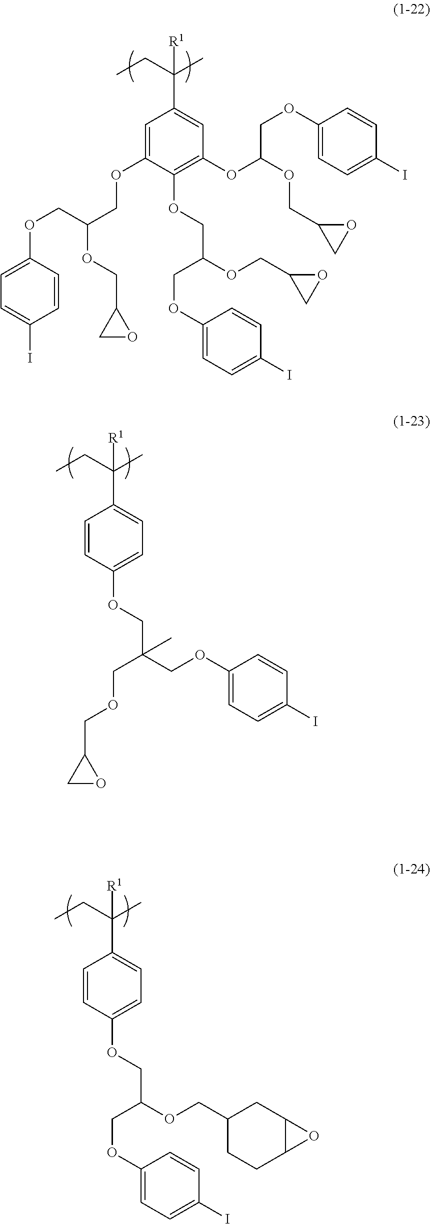

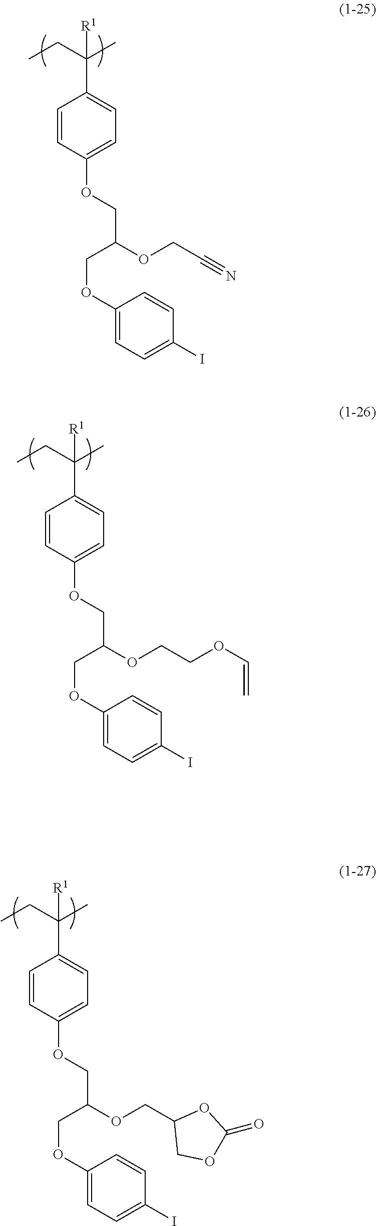

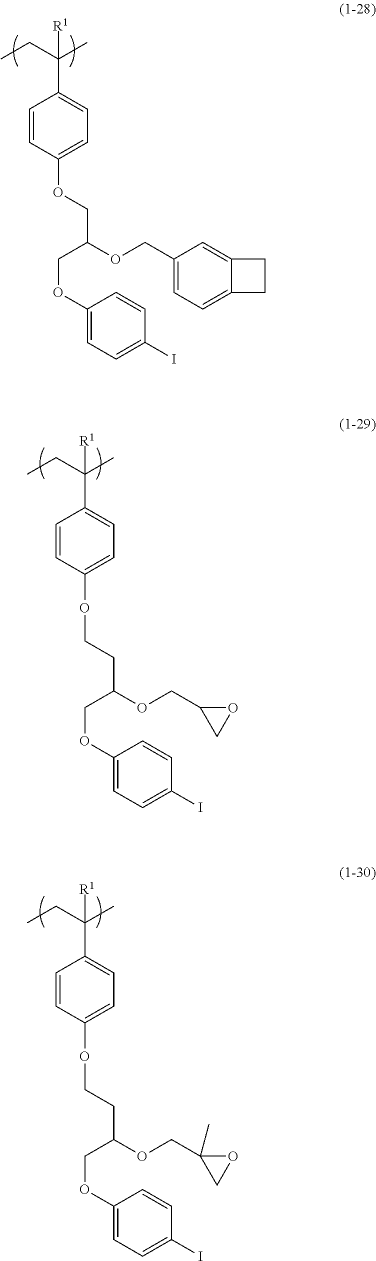

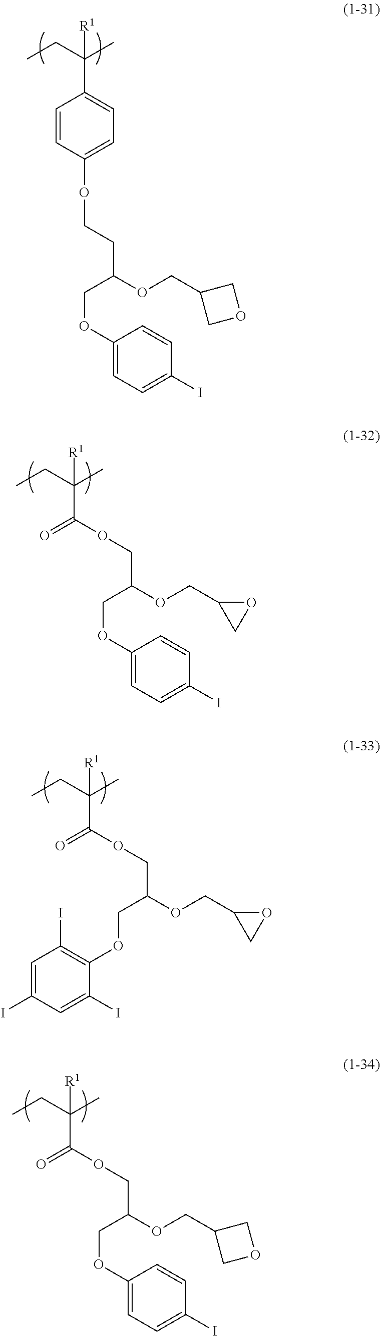

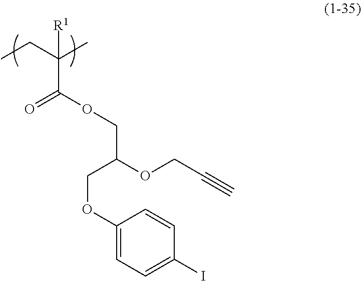

In the above formulas (1-1) to (1-35), R¹ has the same definition as that in the above formula (1).

The lower limit of the content ratio of the repeating unit (1) (when there are a plurality of types thereof, the total content ratio is taken) in all the repeating units constituting the polymer [A] is preferably 10 mol %. The lower limit of the content ratio may be 20 mol %, 30 mol %, or 40 mol %. The upper limit of the content ratio may be 100 mol %, that is, the polymer [A] may be a homopolymer of the repeating unit (1). When the polymer [A] is a copolymer, the upper limit of the content ratio of the repeating unit (1) may be 99 mol %, 95 mol % or 90 mol %.

The polymer [A] may further have a repeating unit represented by formula (4) (excluding the case of being the above formula (1)) (hereinafter, also referred to as “repeating unit (2)”). The polymer [A] may have one type or two or more types of the repeating unit (2).

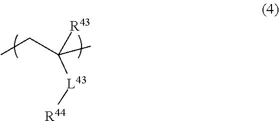

In the above formula (2), R⁴³ is a hydrogen atom or a substituted or unsubstituted monovalent hydrocarbon group having 1 to 20 carbon atoms. L⁴³ is a single bond or a divalent linking group. R⁴⁴ is the organic group (A).

As the monovalent hydrocarbon group having 1 to 20 carbon atoms represented by R⁴³, a monovalent hydrocarbon group having 1 to 20 carbon atoms represented by R¹ in the above formula (1) can be suitably employed. When R⁴³ has a substituent, a substituent that can be possessed by R¹ of the above formula (1) can be suitably employed.

As the divalent linking group represented by L⁴³, a divalent linking group represented by L¹ in the above formula (1) can be suitably employed. L⁴³ is preferably a single bond, —COO—* (* is a bond to R⁴⁴), or a benzenediyl group.

Specific examples of the repeating unit (2) include repeating units represented by formulas (4-1) to (4-16).

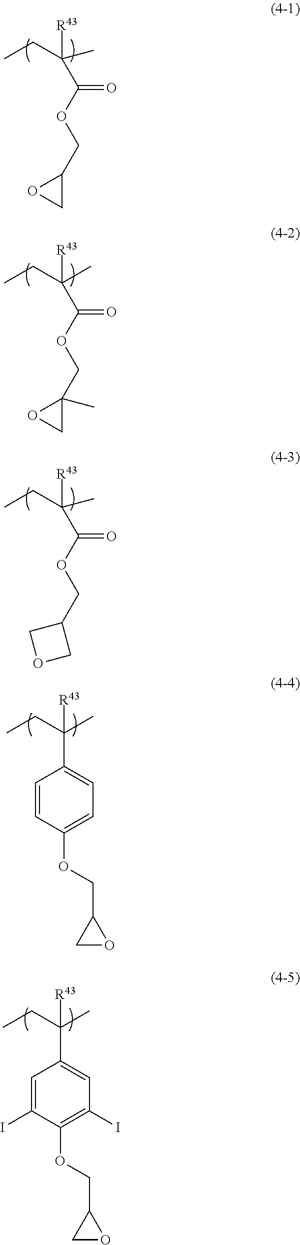

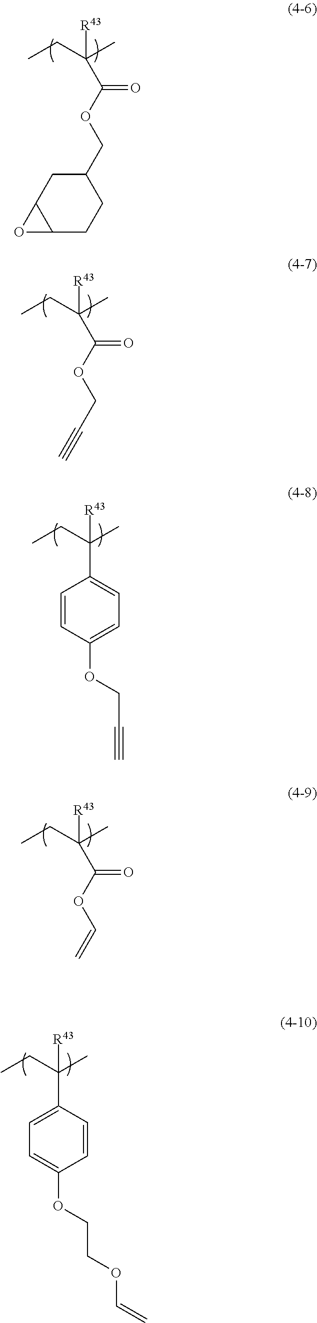

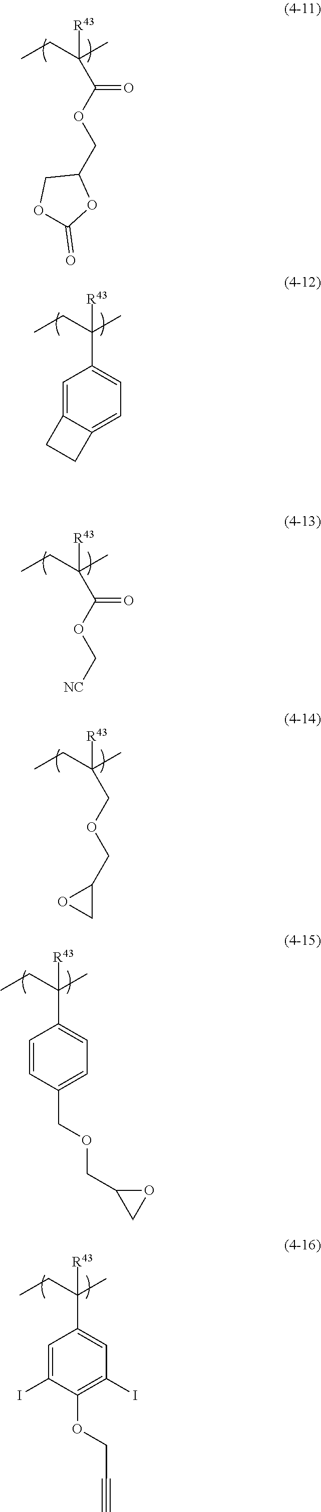

In the above formulas (4-1) to (4-16), R⁴³ has the same definition as that in the above formula (4).

When the polymer [A] contains the repeating unit (2), the lower limit of the content ratio of the repeating unit (2) (when there are a plurality of types thereof, the total content ratio is taken) in all the repeating units constituting the polymer [A] is preferably 1 mol %, more preferably 20 mol %, and still more preferably 30 mol %. The upper limit of the content is preferably 80 mol %, more preferably 70 mol %, and still more preferably 60 mol %. When the content ratio of the repeating unit (2) is within the above range, solvent resistance and resist pattern rectangularity can be exhibited at a high level.

The polymer [A] may have, as another repeating unit (excluding the case of being the above formula (1)), a repeating unit containing a structure that generates an acid by exposure, such as an onium salt structure containing a sulfonate anion and a sulfonium cation, and an onium salt structure containing a sulfonate anion and an iodonium cation; a repeating unit having at least one hydroxy group; a repeating unit having a fluorine atom; and the like. When the polymer [A] contains another repeating unit, the lower limit of the content ratio of the other repeating unit (when there are a plurality of types thereof, the total content ratio is taken) in all the repeating units constituting the polymer [A] is preferably 1 mol %, more preferably 5 mol %, and still more preferably 10 mol %. The upper limit of the content is preferably 40 mol %, more preferably 30 mol %, and still more preferably 20 mol %.

The lower limit of the weight average molecular weight of the polymer [A] is preferably 2000, more preferably 3000, still more preferably 4000, and particularly preferably 5000. The upper limit of the molecular weight is preferably 15000, more preferably 12000, still more preferably 10000, and particularly preferably 8000. The weight average molecular weight is measured as described in Examples.

The lower limit of the polydispersity index (PDI: Mw/Mn) of the polymer [A] is usually 1, and more preferably 1.1. The upper limit of the PDI is usually 5, preferably 3, and more preferably 2.

The lower limit of the content ratio of the polymer [A] in the composition for forming a resist underlayer film is preferably 0.05% by mass, more preferably 0.1% by mass, still more preferably 0.15% by mass, and particularly preferably 0.2% by mass in the total mass of the polymer [A] and the solvent [B]. The upper limit of the content ratio is preferably 1% by mass, more preferably 0.8% by mass, still more preferably 0.6% by mass, particularly preferably 0.4% by mass in the total mass of the polymer [A] and the solvent [B].

The lower limit of the content ratio of the polymer [A] to the components other than the solvent [B] in the composition for forming a resist underlayer film is preferably 40% by mass, more preferably 50% by mass, and still more preferably 60% by mass. The upper limit of the content ratio is preferably 100% by mass, and may be 90% by mass, and also may be 85% by mass.

### [Method for Synthesizing Polymer [A]]

The polymer [A] can be synthesized by performing radical polymerization, ion polymerization, polycondensation, polyaddition, addition condensation, or the like depending on the type of the monomer. For example, when the polymer [A] is synthesized by radical polymerization, the polymer can be synthesized by polymerizing monomers which will afford respective repeating units using a radical polymerization initiator of the like in an appropriate solvent.

Examples of the radical polymerization initiator include azo radical initiators, such as azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile), dimethyl 2,2′-azobisisobutyrate, and dimethyl-2,2′-azobis(2-methylpropionate); and peroxide radical initiators, such as benzoyl peroxide, t-butyl hydroperoxide and cumene hydroperoxide. These radical initiators may be used singly, or two or more of them may be used in combination.

As the solvent to be used for the polymerization, the solvent [B] described later can be suitably employed. The solvents to be used for the polymerization may be used singly, or two or more solvents may be used in combination.

The reaction temperature in the polymerization is usually 40° C. to 150° C., and preferably 50° C. to 120° C. The reaction time is usually 1 hour to 48 hours, and preferably 1 hour to 24 hours.

### <Solvent [B]>

The solvent [B] is not particularly limited as long as it can dissolve or disperse the compound [A], and optional components contained as necessary.

Examples of the solvent [B] include a hydrocarbon-based solvent, an ester-based solvent, an alcohol-based solvent, a ketone-based solvent, an ether-based solvent, and a nitrogen-containing solvent. The solvent [B] may be used singly or two or more kinds thereof may be used in combination.

Examples of the hydrocarbon-based solvent include aliphatic hydrocarbon-based solvents such as n-pentane, n-hexane, and cyclohexane, and aromatic hydrocarbon-based solvents such as benzene, toluene, and xylene.

Examples of the ester-based solvent include carbonate-based solvents such as diethyl carbonate, acetic acid monoacetate ester-based solvents such as methyl acetate and ethyl acetate, lactone-based solvents such as γ-butyrolactone, polyhydric alcohol partial ether carboxylate-based solvents such as diethylene glycol monomethyl ether acetate and propylene glycol monomethyl ether acetate, and lactate ester-based solvents such as methyl lactate and ethyl lactate.

Examples of the alcohol-based solvent include monoalcohol-based solvents such as methanol, ethanol, n-propanol, 4-methyl-2-pentanol, and 2,2-dimethyl-1-propanol, and polyhydric alcohol-based solvents such as ethylene glycol and 1,2-propylene glycol.

Examples of the ketone-based solvent include chain ketone-based solvents such as methyl ethyl ketone and methyl isobutyl ketone, 2-heptanone, and cyclic ketone-based solvents such as cyclohexanone.

Examples of the ether-based solvent include chain ether-based solvents such as n-butyl ether, cyclic ether-based solvents such as tetrahydrofuran, polyhydric alcohol ether-based solvents such as propylene glycol dimethyl ether, and polyhydric alcohol partial ether-based solvents such as diethylene glycol monomethyl ether, propylene glycol monomethyl ether.

Examples of the nitrogen-containing solvent include chain nitrogen-containing solvents such as N,N-dimethylacetamide, and cyclic nitrogen-containing solvents such as N-methylpyrrolidone.

As the solvent [B], a ketone-based solvent, an ether-based solvent, or an ester-based solvent is preferable, a cyclic ketone-based solvent, a polyhydric alcohol partial ether-based solvent, or a polyhydric alcohol partial ether carboxylate-based solvent is more preferable, and cyclohexanone, propylene glycol monomethyl ether, or propylene glycol monomethyl ether acetate is still more preferable.

### [Optional Component]

The composition for forming a resist underlayer film may contain an optional component as long as the effects of the present disclosure are not impaired. Examples of the optional component include a crosslinking agent, an acid generator, a dehydrating agent, an acid diffusion controlling agent, and a surfactant. The optional component can be used singly or in combination of two or more kinds thereof, and the content ratio of the optional component in the total mass of the polymer [A] and the optional component is preferably 30% by mass or less and preferably 20% by mass or less.

### [Method for Preparing Composition for Forming Resist Underlayer Film]

The composition for forming a resist underlayer film can be prepared by mixing the polymer [A], the solvent [B] and, as necessary, an optional component in a prescribed ratio and preferably filtering the resulting mixture through a membrane filter having a pore size of 0.5 μm or less, or the like.

### <<Method for Producing Semiconductor Substrate>>

The method for producing a semiconductor substrate includes directly or indirectly applying a composition for forming a resist underlayer film to a substrate (hereinafter, also referred to as “application step (I)”); applying a composition for forming a resist film to a resist underlayer film formed by applying the composition for forming a resist underlayer film (hereinafter, also referred to as “application step (II)”); exposing a resist film formed by applying the composition for forming a resist film to radiation (hereinafter, also referred to as “exposure step”); and developing at least the exposed resist film (hereinafter, also referred to as “development step”).

By the method for producing a semiconductor substrate, a resist underlayer film excellent in solvent resistance and resist pattern rectangularity can be formed due to the use of a prescribed composition for forming a resist underlayer film in the application step (I), so that a semiconductor substrate having a favorable pattern shape can be produced.

Preferably, the method for producing a semiconductor substrate further includes a step of, before the application step (II), a step of heating the resist underlayer film formed by the step of applying a composition for forming a resist underlayer film at 200° C. or higher (hereinafter, also referred to as “heating step”).

The method for producing a semiconductor substrate may further include, as necessary, a step of directly or indirectly forming a silicon-containing film on the substrate (hereinafter, also referred to as “silicon-containing film formation step”) before the application step (I).

Hereinafter, each step in the case of including the heating step, which is a suitable step, and the silicon-containing film formation step, which is an optional step, will be described.

### [Silicon-Containing Film Forming Step]

In this step performed before the application step (I), a silicon-containing film is formed directly or indirectly on a substrate.

Examples of the substrate include metallic or semimetallic substrates such as a silicon substrate, an aluminum substrate, a nickel substrate, a chromium substrate, a molybdenum substrate, a tungsten substrate, a copper substrate, a tantalum substrate, and a titanium substrate. Among them, a silicon substrate is preferred. The substrate may be a substrate having a silicon nitride film, an alumina film, a silicon dioxide film, a tantalum nitride film, or a titanium nitride film formed thereon.

The silicon-containing film can be formed by, for example, application, chemical vapor deposition (CVD), atomic layer deposition (ALD), or the like of a composition for forming a silicon-containing film. Examples of a method for forming a silicon-containing film by application of a composition for forming a silicon-containing film include a method in which a coating film formed by applying a composition for forming a silicon-containing film directly or indirectly to the substrate is cured by exposure and/or heating. As a commercially available product of the composition for forming a silicon-containing film, for example, “NFC SOG01”, “NFC SOG04”, or “NFC SOG080” (all manufactured by JSR Corporation) can be used. By chemical vapor deposition (CVD) or atomic layer deposition (ALD), a silicon oxide film, a silicon nitride film, a silicon oxynitride film, or an amorphous silicon film can be formed.

Examples of the radiation to be used for the exposure include electromagnetic waves such as visible rays, ultraviolet rays, far ultraviolet rays, X-rays, and γ-rays and corpuscular rays such as electron beam, molecular beams, and ion beams.

The lower limit of the temperature in heating the coating film is preferably 90° C., more preferably 150° C., and still more preferably 200° C. The upper limit of the temperature is preferably 550° C., more preferably 450° C., and still more preferably 300° C.

The lower limit of the average thickness of the silicon-containing film is preferably 1 nm, more preferably 10 nm, and still more preferably 20 nm. The upper limit is preferably 20,000 nm, more preferably 1,000 nm, and still more preferably 100 nm. The average thickness of the silicon-containing film can be measured in the same manner as for the average thickness of the resist underlayer film.

Examples of a case where the silicon-containing film is formed indirectly on the substrate include a case where the silicon-containing film is formed on a low dielectric insulating film or an organic underlayer film formed on the substrate.

### [Application Step (I)]

In this step, a composition for forming a resist underlayer film is applied to the silicon-containing film formed on the substrate. The method of the application of the composition for forming a resist underlayer film is not particularly limited, and the application can be performed by an appropriate method such as spin coating, cast coating, or roll coating. As a result, a coating film is formed, and volatilization of the solvent [B] or the like occurs, so that a resist underlayer film is formed.

The lower limit of the average thickness of the resist underlayer film to be formed is preferably 0.5 nm, more preferably 1 nm, and still more preferably 2 nm. The upper limit of the average thickness is preferably 50 nm, more preferably 20 nm, still more preferably 10 nm, and particularly preferably 7 nm. The average thickness is measured as described in Examples.

When the composition for forming a resist underlayer film is applied directly to the substrate, the silicon-containing film formation step may be omitted.

### [Heating Step]

Next, the resist underlayer film formed by the application step (I) is heated. Formation of a crosslinked structure by a specific group in the polymer [A] is promoted by the heating of the resist underlayer film. This step is performed before the application step (II).

The heating of the coating film may be performed either in the air atmosphere or in a nitrogen atmosphere. The lower limit of the heating temperature is just required to be 180° C., but is preferably 200° C., more preferably 210° C., and still more preferably 220° C. The upper limit of the heating temperature is preferably 400° C., more preferably 350° C., and still more preferably 280° C. The lower limit of the heating time is preferably 15 seconds, and more preferably 30 seconds. The upper limit of the time is preferably 800 seconds, more preferably 400 seconds, and still more preferably 200 seconds.

### [Application Step (II)]

In this step, a composition for forming a resist film is formed on the resist underlayer film formed by the step of applying a composition for forming a resist underlayer film. The method of applying the composition for forming a resist film is not particularly limited, and examples thereof include a spin coating method.

Describing this step more in detail, for example, a resist composition is applied such that a resist film formed comes to have a prescribed thickness, and then prebaking (hereinafter also referred to as “PB”) is performed to volatilize the solvent in the coating film. As a result, a resist film is formed.

The PB temperature and the PB time may be appropriately determined according to the type and the like of the composition for forming a resist film to be used. The lower limit of the PB temperature is preferably 30° C., and more preferably 50° C. The upper limit of the PB temperature is preferably 200° C., and more preferably 150° C. The lower limit of the PB time is preferably 10 seconds, and more preferably 30 seconds. The upper limit of the PB time is preferably 600 seconds, and more preferably 300 seconds.

The composition for forming a resist film used in this step is suitably a composition that is exposed to extreme ultraviolet rays, and examples of the composition include a positive or negative chemically amplified resist composition that contains a radiation-sensitive acid generator and a metal-containing resist composition that contains a metal such as tin, zirconium, or hafnium.

### [Exposure Step]

In this step, a resist film formed in the step of applying a composition for forming a resist film is exposed to radiation. This step causes a difference in solubility in a basic solution as a developer between an exposed portion and an unexposed portion in the resist film. More specifically, the solubility of the exposed portion in a basic solution in the resist film increases.

Radiation to be used for the exposure can be appropriately selected according to the type or the like of the composition for forming a resist film to be used. Examples thereof include electromagnetic rays such as visible rays, ultraviolet rays, far-ultraviolet, X-rays, and γ-rays and corpuscular rays such as electron beam, molecular beams, and ion beams. Among these, far-ultraviolet rays are preferable, and KrF excimer laser light (wavelength: 248 nm), ArF excimer laser light (wavelength: 193 nm), F₂ excimer laser light (wavelength: 157 nm), Kr₂ excimer laser light (wavelength: 147 nm), ArKr excimer laser light (wavelength: 134 nm) or extreme ultraviolet rays (wavelength: 13.5 nm, etc., also referred to as “EUV”) are more preferred, and ArF excimer laser light or EUV is even more preferred. Further, the exposure conditions can be determined as appropriate depending on the type of resist film forming composition used.

In this step, post exposure baking (hereinafter, also referred to as “PEB”) can be performed after the exposure in order to improve the resist film performance such as resolution, pattern profile, and developability. The PEB temperature and the PEB time may be appropriately determined according to the type and the like of the composition for forming a resist film to be used. The lower limit of the PEB temperature is preferably 50° C., and more preferably 70° C. The upper limit of the PEB temperature is preferably 200° C., and more preferably 150° C. The lower limit of the PEB time is preferably 10 seconds, and more preferably 30 seconds. The upper limit of the PEB time is preferably 600 seconds, and more preferably 300 seconds.

### [Development Step]

In this step, the exposed resist film is developed. At this time, a part of the resist underlayer film may also be developed. Examples of the developer to be used for the development include an aqueous alkaline solution (alkaline developer) and an organic solvent-containing solution (organic solvent developer).

The basic solution for the alkali development is not particularly limited, and a publicly known basic solution can be used. Examples of the basic solution for the alkali development include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, and 1,5-diazabicyclo-[4.3.0]-5-nonene. Among them, the aqueous TMAH solution is preferable, and a 2.38% by mass aqueous TMAH solution is more preferable.

Examples of the organic solvent developer in the case of performing organic solvent development include the same as those disclosed as the examples of the solvent [B] described above. As the organic solvent developer, an ester-based solvent, an ether-based solvent, an alcohol-based solvent, a ketone-based solvent and/or a hydrocarbon-based solvent is preferable, a ketone-based solvent is more preferable, and 2-heptanone is particularly preferable.

In this step, washing and/or drying may be performed after the development.

### [Etching Step]

In this step, etching is performed using the resist pattern (and the resist underlayer film pattern) as a mask. The number of times of the etching may be once. Alternatively, etching may be performed a plurality of times, that is, etching may be sequentially performed using a pattern obtained by etching as a mask. From the viewpoint of obtaining a pattern having a favorable shape, etching is preferably performed a plurality of times. When performed a plurality of times, etching is performed to the silicon-containing film, and the substrate sequentially in order. Examples of an etching method include dry etching and wet etching. Dry etching is preferable from the viewpoint of achieving a favorable shape of the pattern of the substrate. In the dry etching, for example, gas plasma such as oxygen plasma is used. As a result of the etching, a semiconductor substrate having a prescribed pattern is obtained.

The dry etching can be performed using, for example, a publicly known dry etching apparatus. The etching gas used for dry etching can be appropriately selected according to the elemental composition of the film to be etched, and for example, fluorine-based gases such as CHF₃, CF₄, C₂F₆, C₃F₈, and SF₆, chlorine-based gases such as Cl₂ and BCl₃, oxygen-based gases such as O₂, O₃, and H₂O, reducing gases such as H₂, NH₃, CO, CO₂, CH₄, C₂H₂, C₂H₄, C₂H₆, C₃H₄, C₃H₆, C₃H₈, HF, HI, HBr, HCl, NO, and BCl₃, and inert gases such as He, N₂ and Ar are used. These gases can also be mixed and used. When the substrate is etched using the pattern of the resist underlayer film as a mask, a fluorine-based gas is usually used.

When the silicon-containing film remains on the substrate or the like after the substrate pattern formation, the silicon-containing film can be removed by performing a removal step.

### EXAMPLES

Hereinafter, Examples are described. The following Examples merely illustrate typical Examples of the present disclosure, and the Examples should not be construed to narrow the scope of the present invention.

### [Weight Average Molecular Weight (Mw), Number Average Molecular Weight (Mn), Polydispersity Index (PDI: Mw/Mn)]

The Mw and Mn of a polymer (x-1) were measured by gel permeation chromatography (detector: differential refractometer) with monodisperse polystyrene standards using GPC columns (“G2000HXL”×2 and “G3000HXL”×1) manufactured by Tosoh Corporation under the following analysis conditions: flow rate: 1.0 mL/min; elution solvent: tetrahydrofuran; column temperature: 40° C. The PDI was calculated from the determined Mw and Mn.

### [Average Thickness of Film]

An average thickness of a film was determined as a value obtained by measuring the film thickness at arbitrary nine points at intervals of 5 cm including the center of the resist underlayer film formed on a silicon wafer (substrate) using a spectroscopic ellipsometer (“M2000D” available from J. A. WOOLLAM Co.) and calculating the average value of the film thicknesses.

### <Synthesis of Polymer [A]>

The polymer [A] having repeating units represented by formulas (A-1) to (A-44) was synthesized by the following procedure. In the formulas, the number attached to each repeating unit represents the content ratio (mol %) of the repeating unit. The composition ratio was confirmed by ¹³C-NMR.

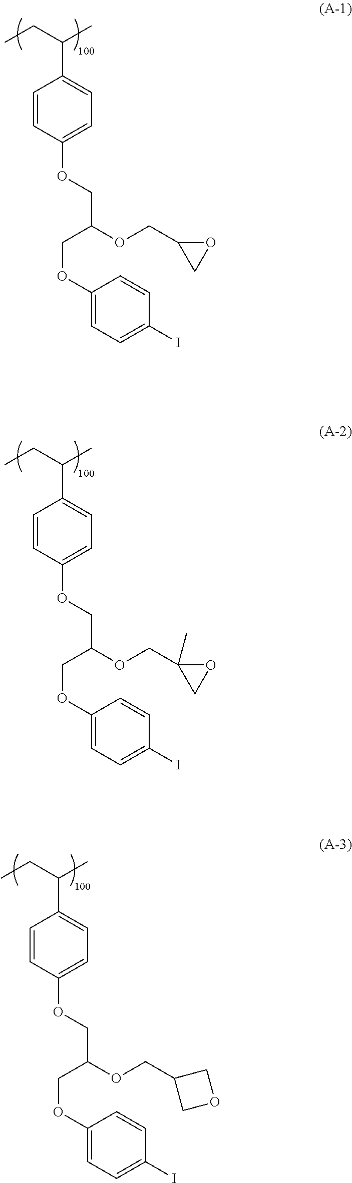

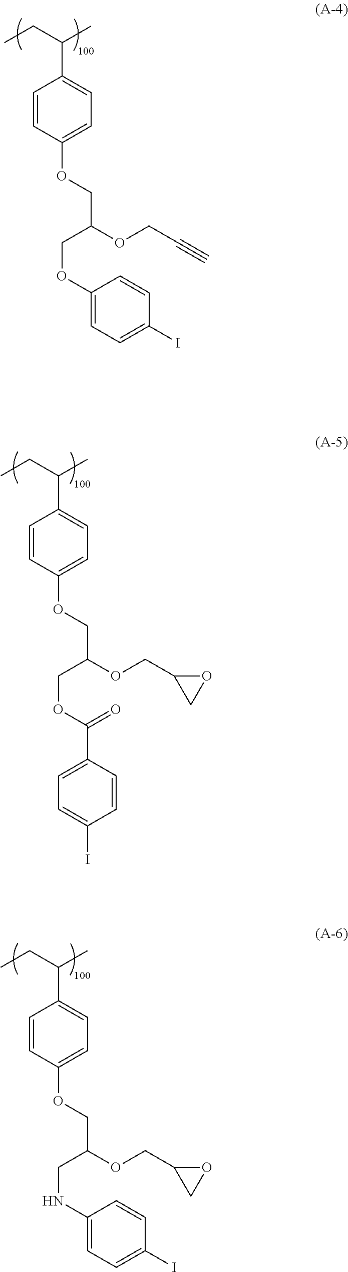

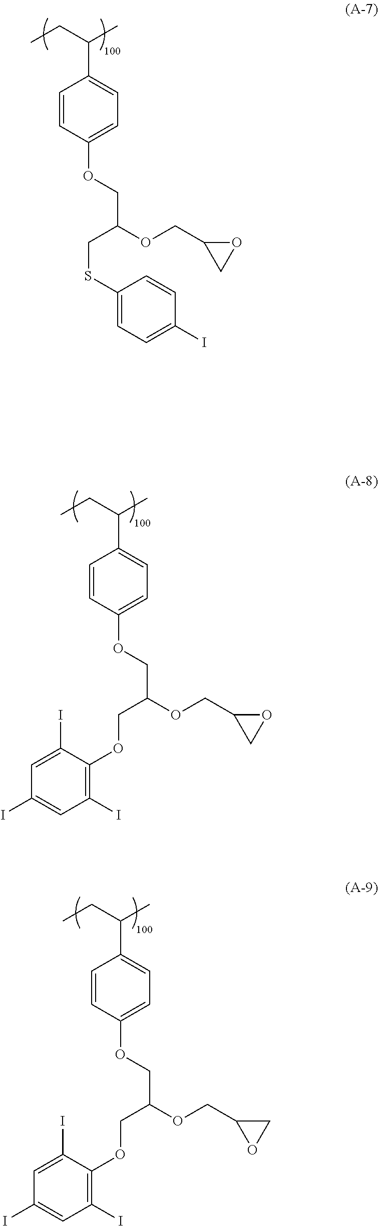

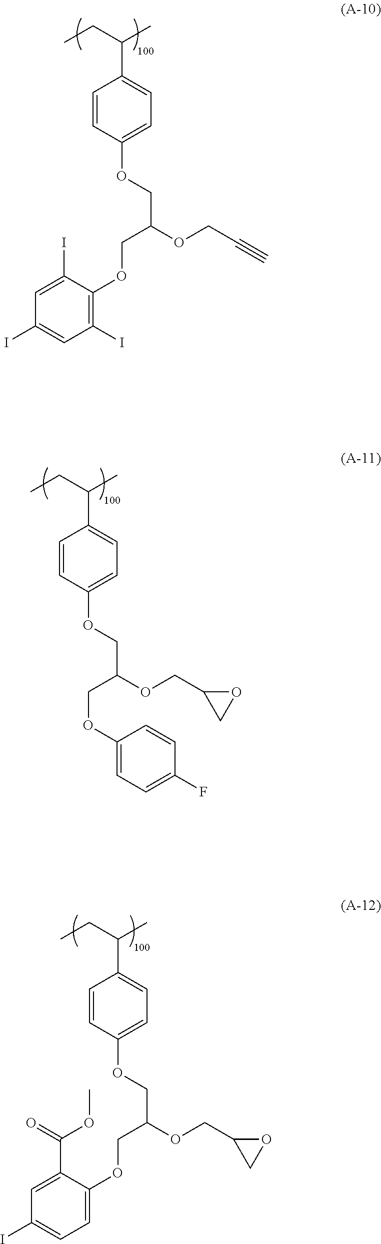

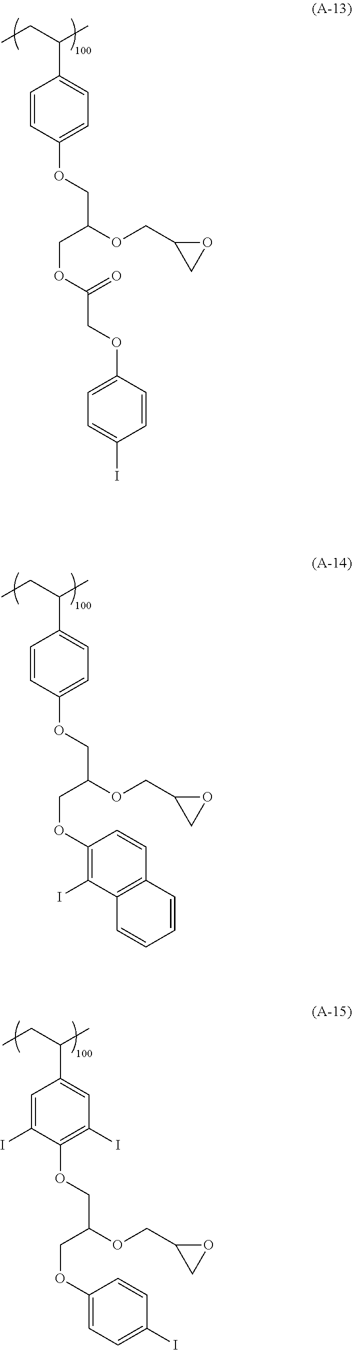

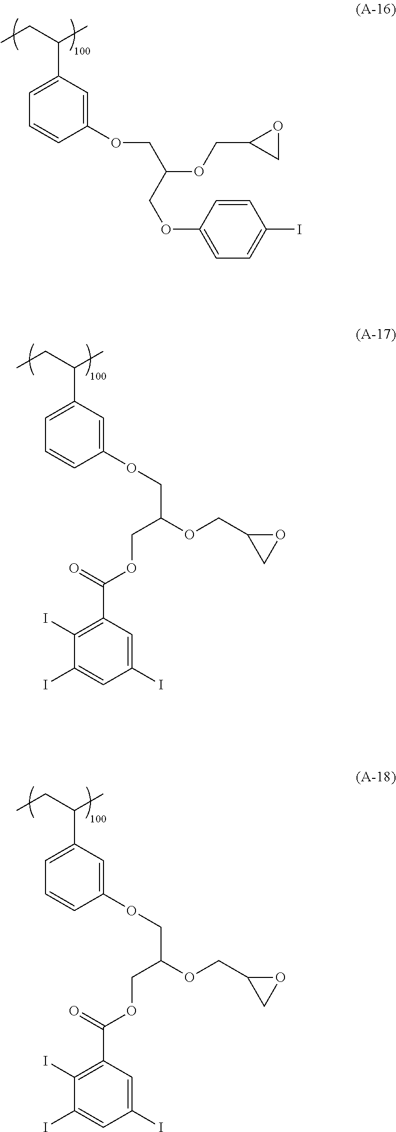

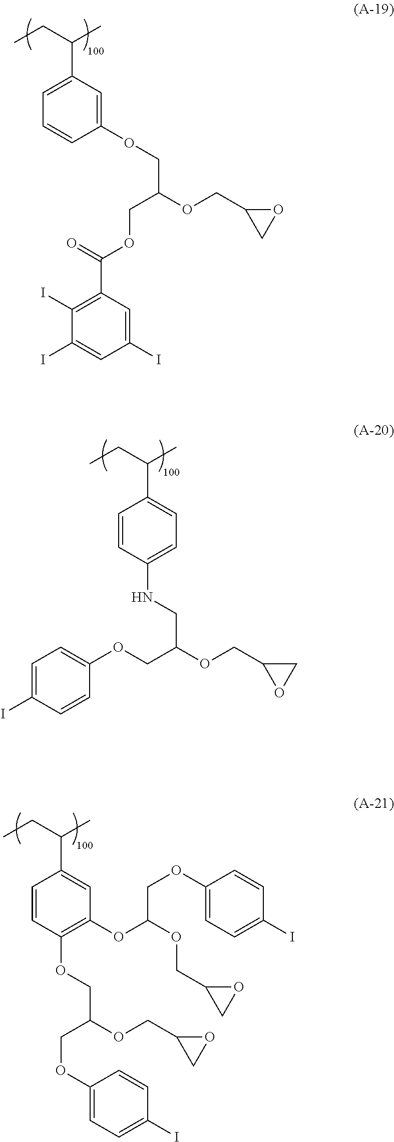

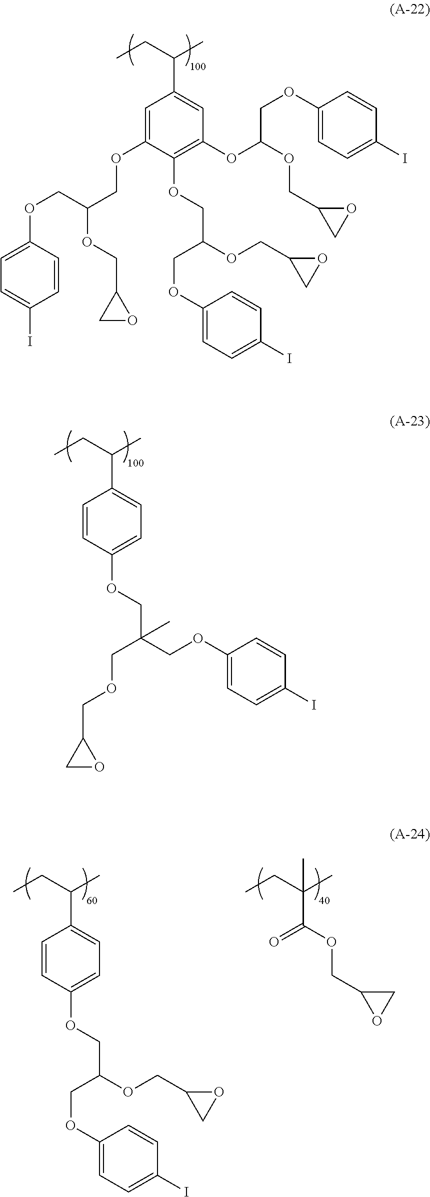

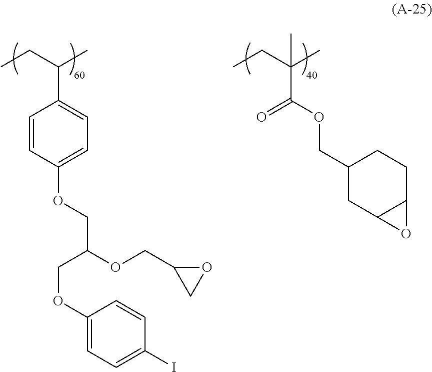

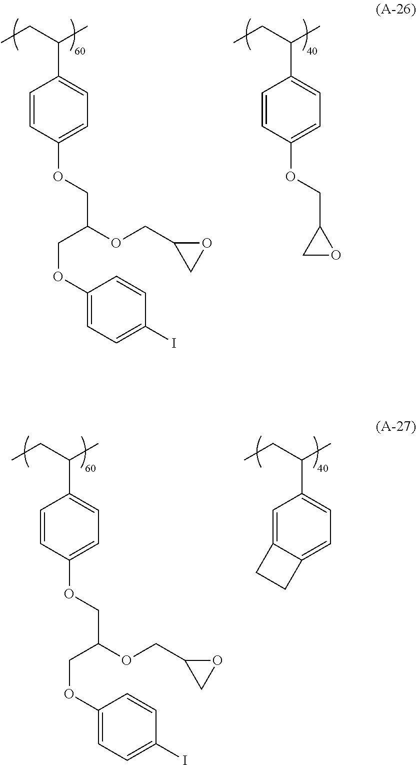

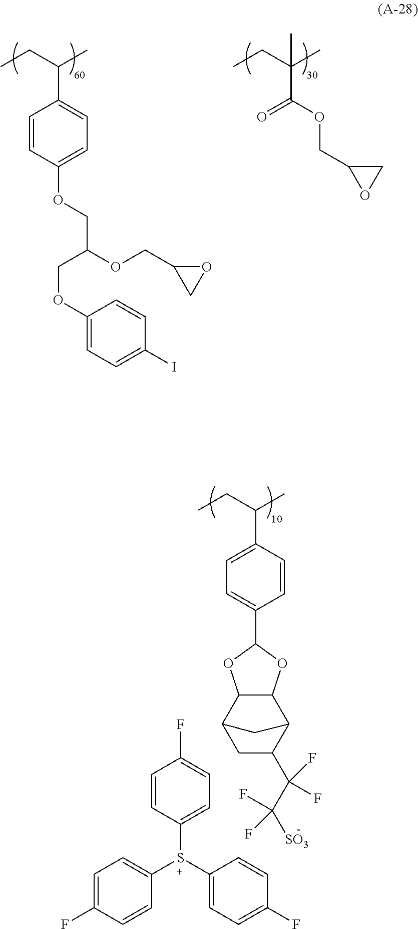

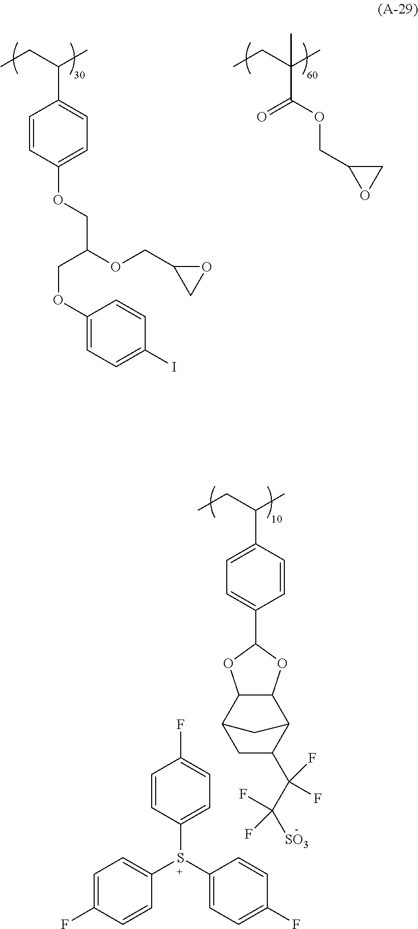

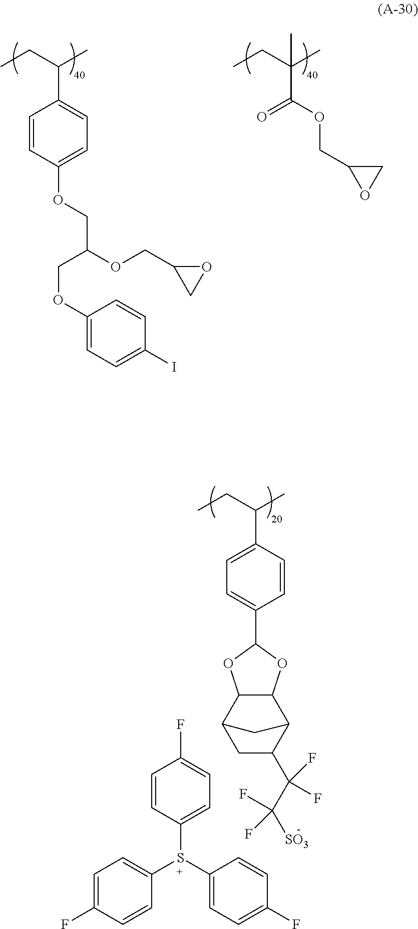

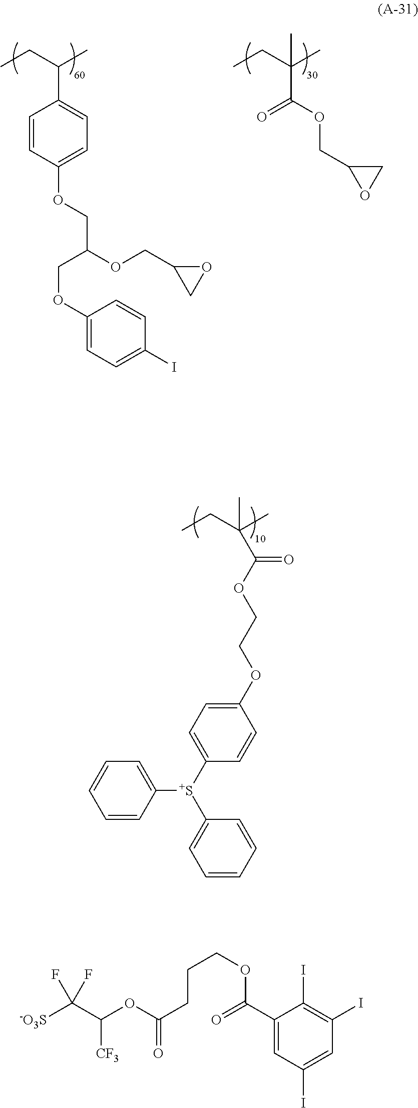

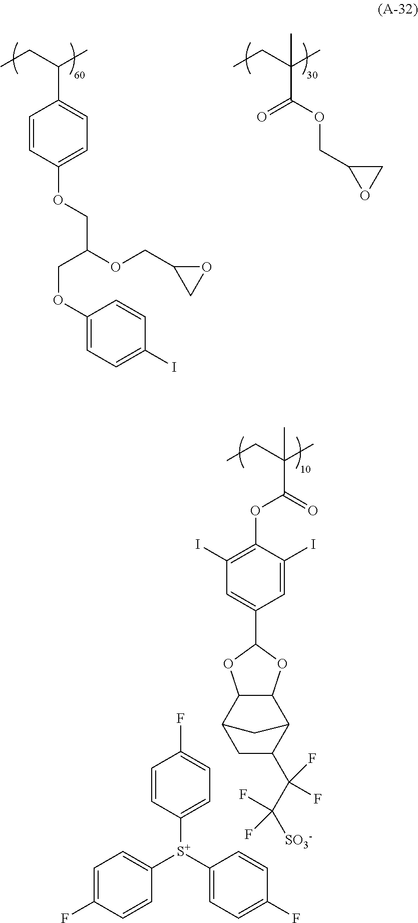

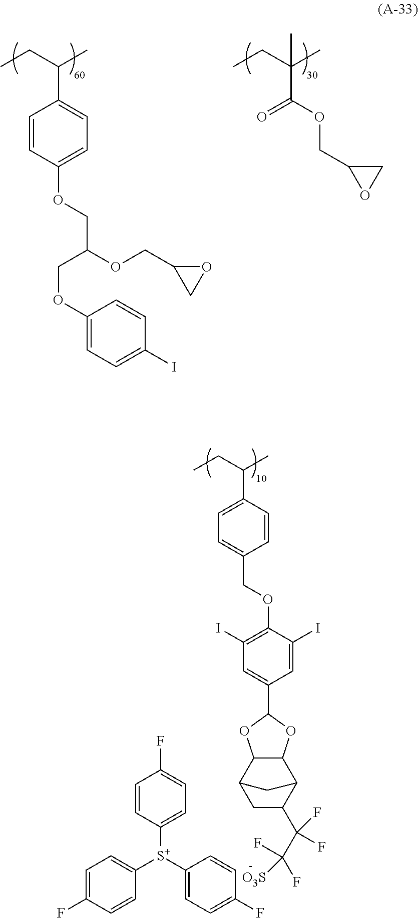

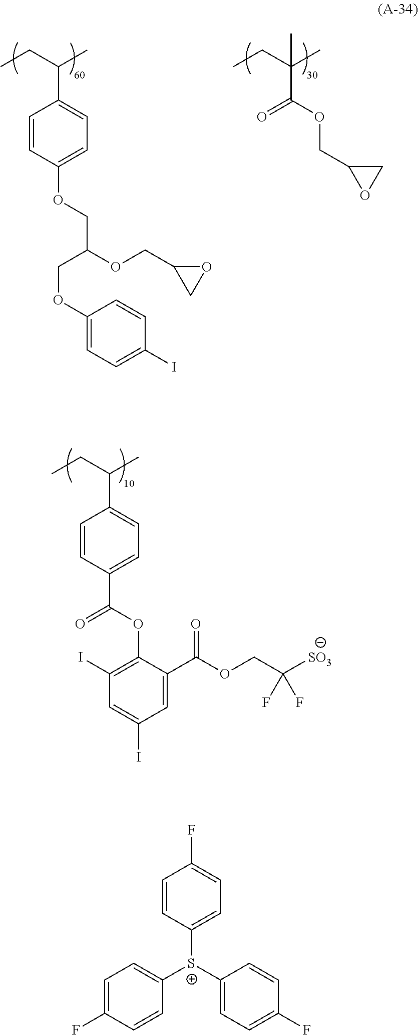

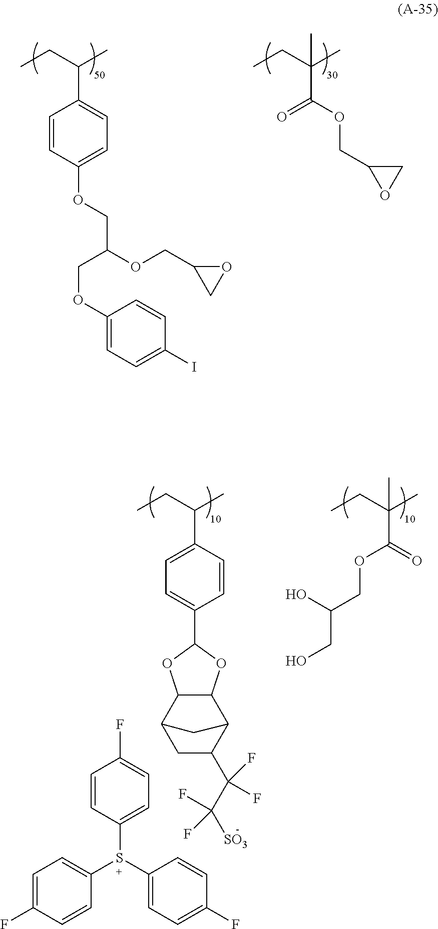

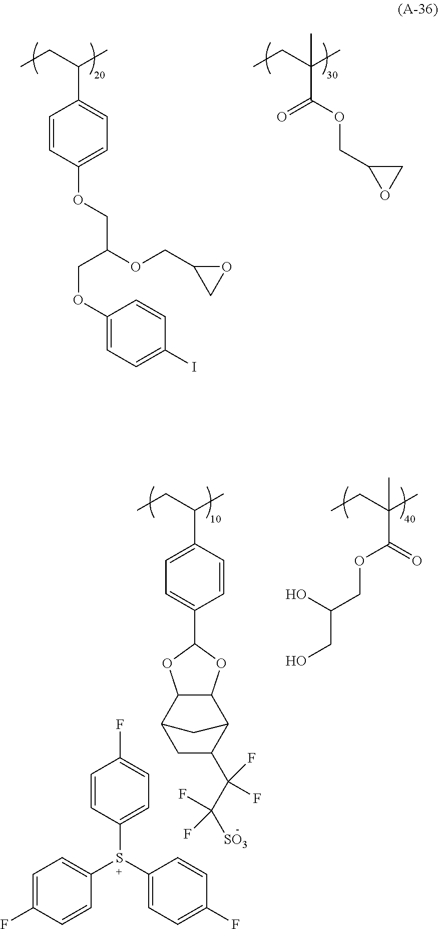

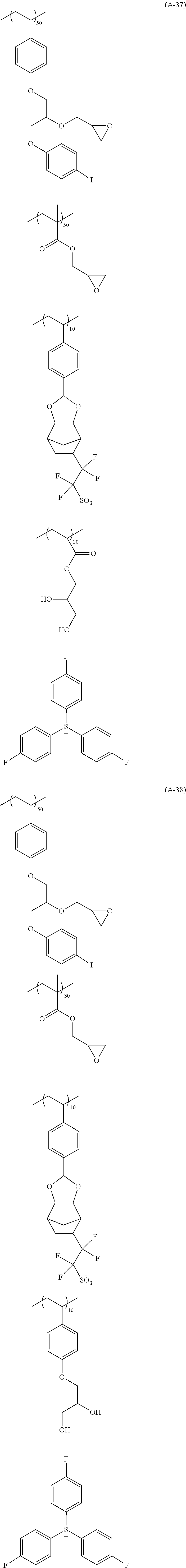

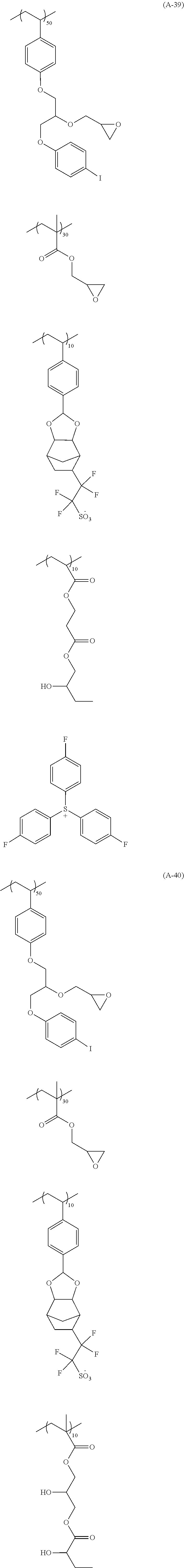

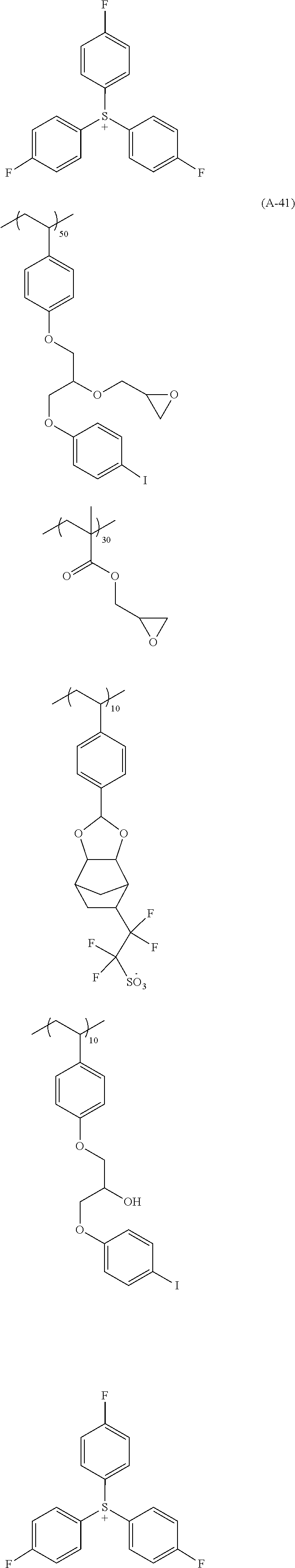

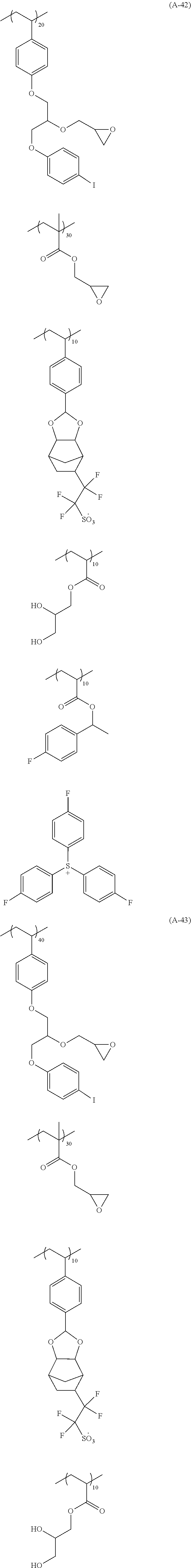

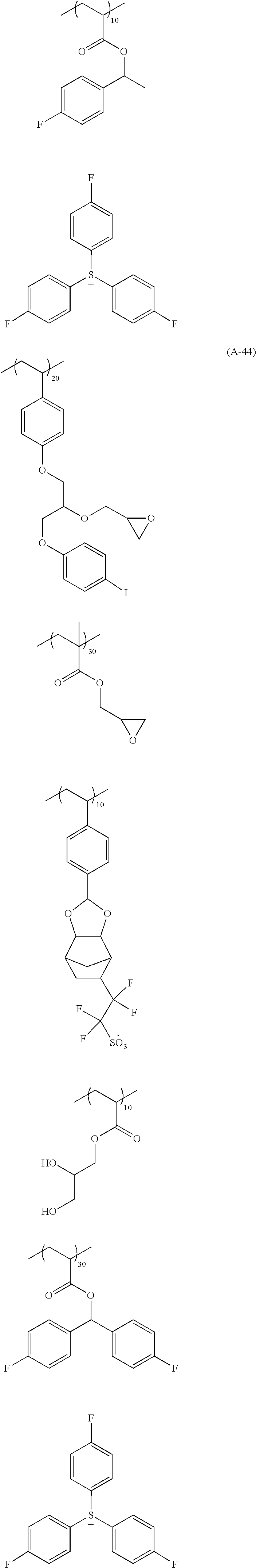

### <Synthesis of Monomer>

The following compounds (a-1) to (a-23) as monomers were used for synthesis of the polymer [A].

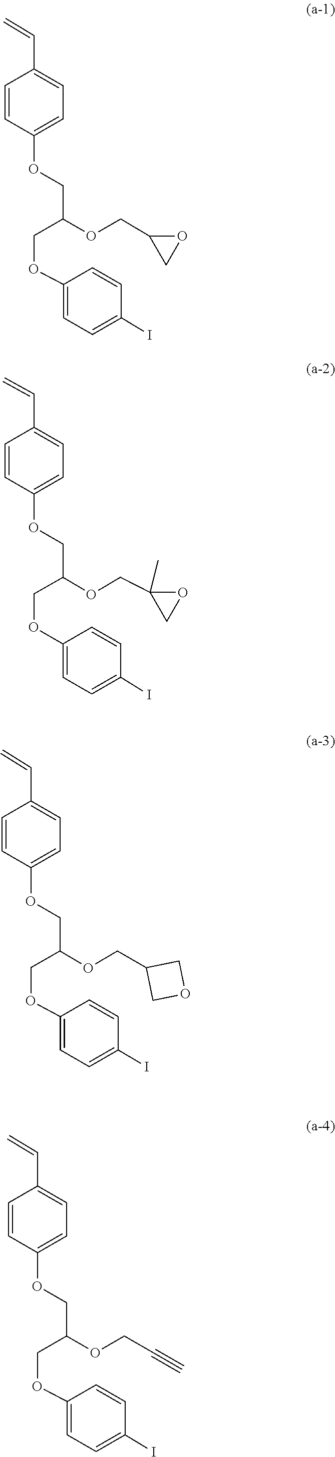 [SMILES: C=Cc1ccc(OCC(COc2ccc(I)cc2)OCC2CO2)cc1 ; C=Cc1ccc(OCC(COc2ccc(I)cc2)OCC2(C)CO2)cc1 ; C=Cc1ccc(OCC(COc2ccc(I)cc2)OCC2COC2)cc1 ; C#CCOC(COc1ccc(I)cc1)COc1ccc(C=C)cc1]

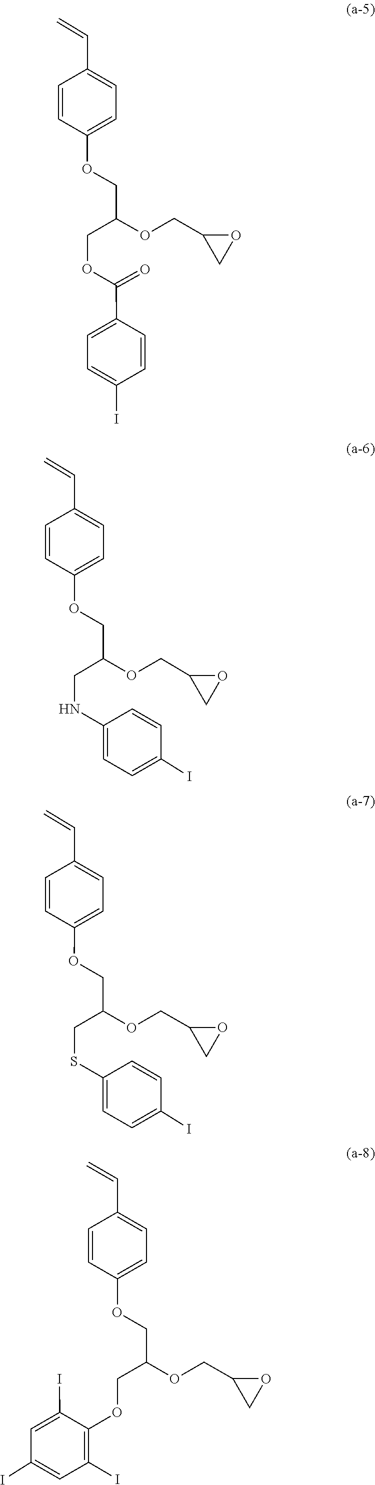 [SMILES: C=Cc1ccc(OCC(COC(=O)c2ccc(I)cc2)OCC2CO2)cc1 ; C=Cc1ccc(OCC(CNc2ccc(I)cc2)OCC2CO2)cc1 ; C=Cc1ccc(OCC(CSc2ccc(I)cc2)OCC2CO2)cc1 ; C=Cc1ccc(OCC(COc2c(I)cc(I)cc2I)OCC2CO2)cc1]

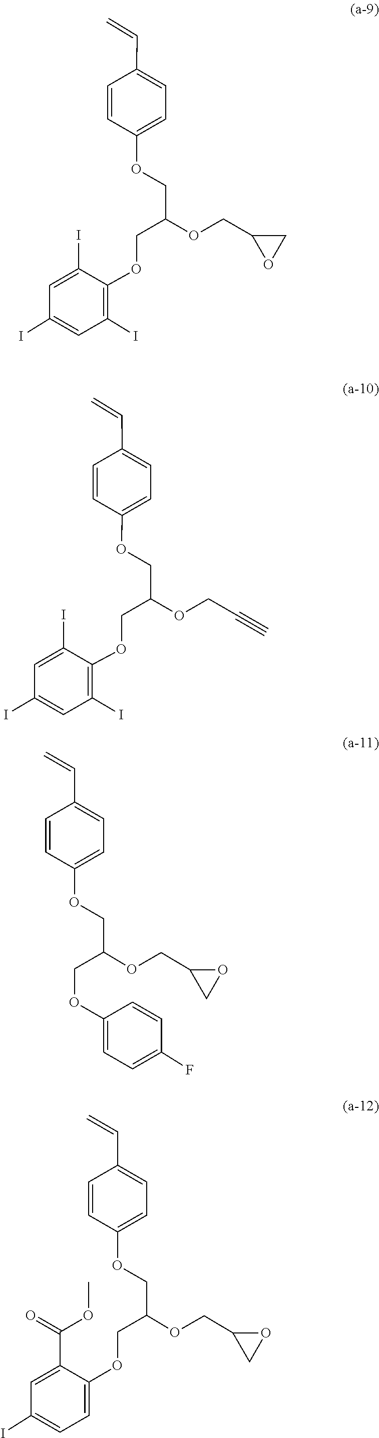

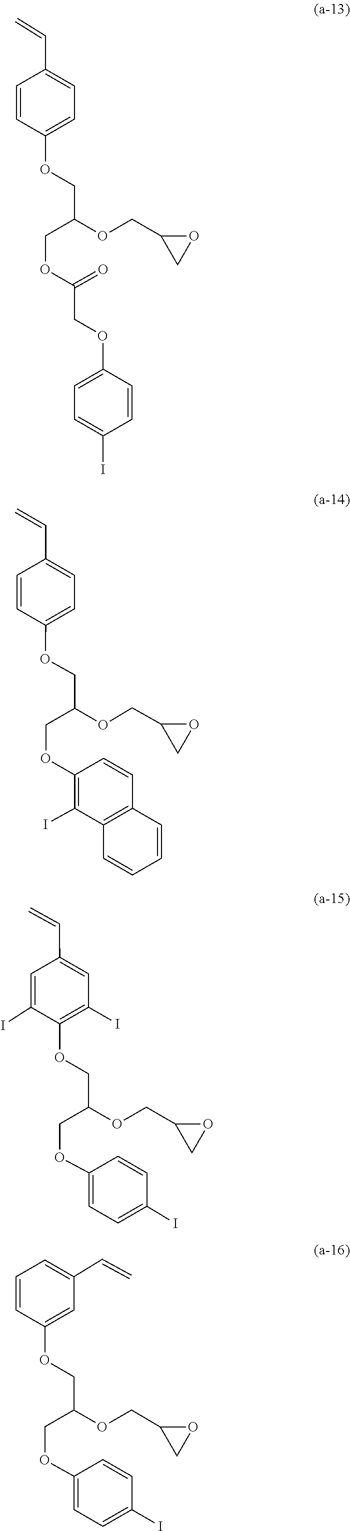

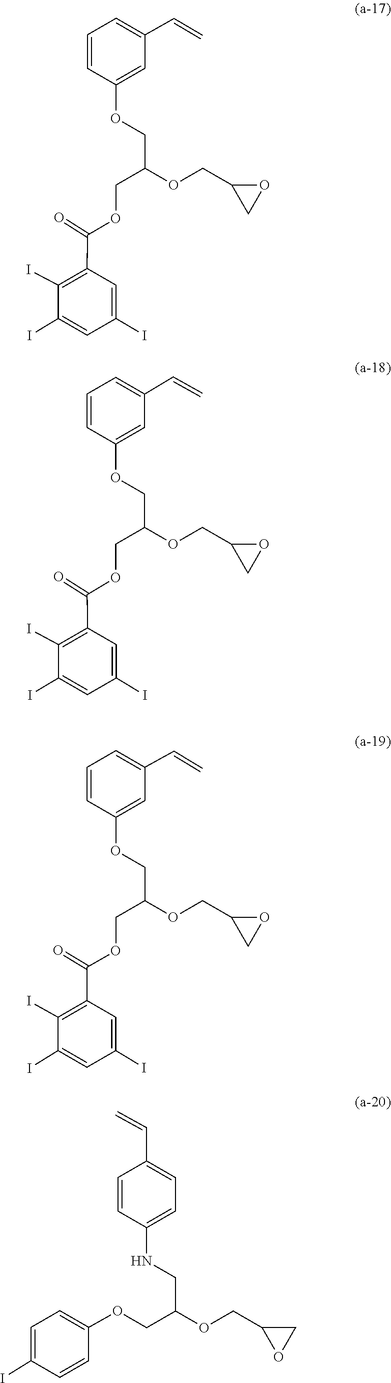 [SMILES: C=Cc1cccc(OCC(COC(=O)c2cc(I)cc(I)c2I)OCC2CO2)c1 ; C=Cc1cccc(OCC(COC(=O)c2cc(I)cc(I)c2I)OCC2CO2)c1 ; C=Cc1cccc(OCC(COC(=O)c2cc(I)cc(I)c2I)OCC2CO2)c1 ; C=Cc1ccc(NCC(COc2ccc(I)cc2)OCC2CO2)cc1]

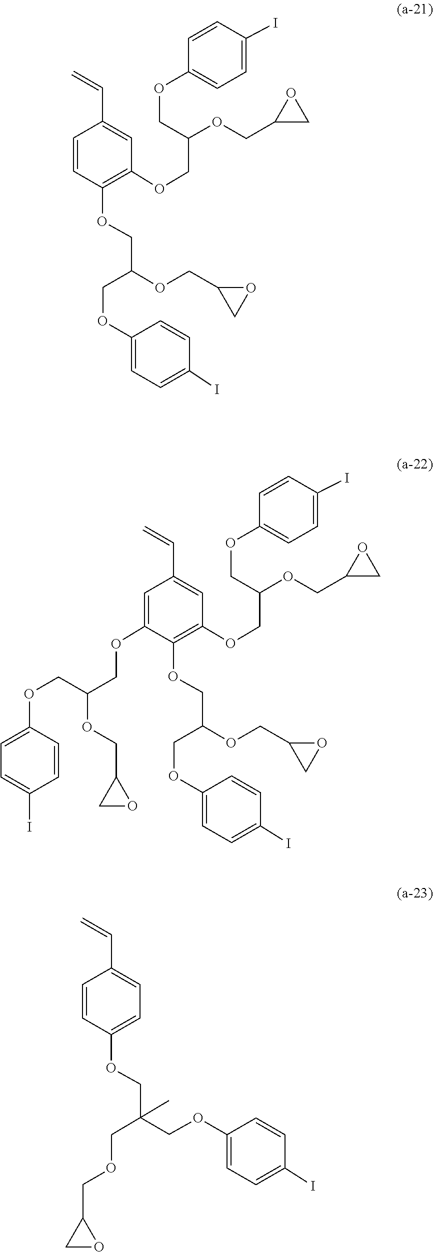 [SMILES: C=Cc1ccc(OCC(COc2ccc(I)cc2)OCC2CO2)c(OCC(COc2ccc(I)cc2)OCC2CO2)c1 ; C=Cc1cc(OCC(COc2ccc(I)cc2)OCC2CO2)c(OCC(COc2ccc(I)cc2)OCC2CO2)c(OCC(COc2ccc(I)cc2)OCC2CO2)c1 ; C=Cc1ccc(OCC(C)(COCC2CO2)COc2ccc(I)cc2)cc1]

The following compounds (f-1) to (f-7), the following compounds (g-1) to (g-11) and the following compounds (h-1) to (h-4) were used as raw materials for synthesizing the monomer.

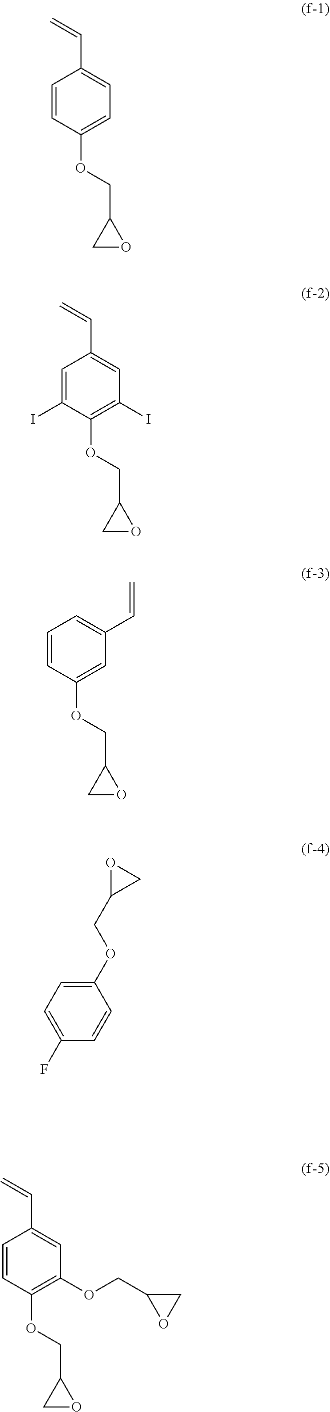 [SMILES: C=Cc1ccc(OCC2CO2)cc1 ; C=Cc1cc(I)c(OCC2CO2)c(I)c1 ; C=Cc1cccc(OCC2CO2)c1 ; Fc1ccc(OCC2CO2)cc1 ; C=Cc1ccc(OCC2CO2)c(OCC2CO2)c1]

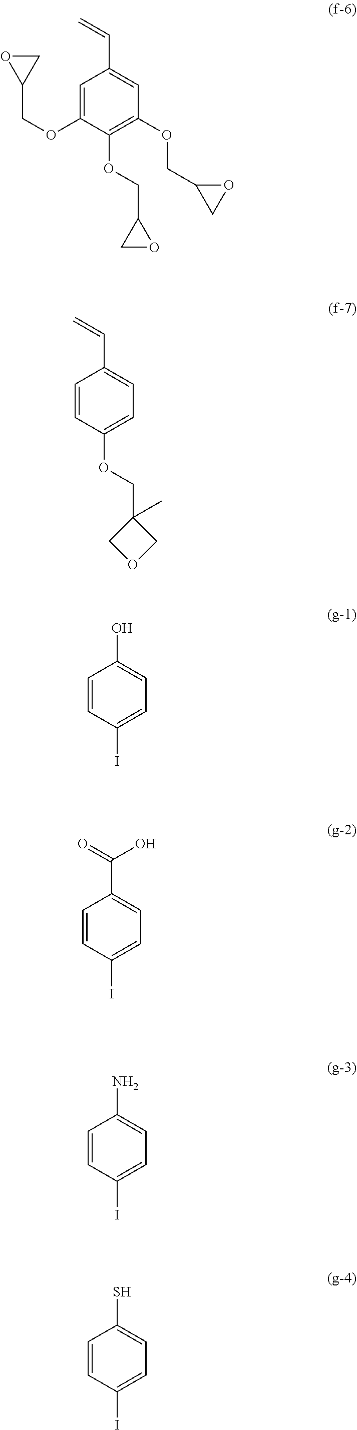 [SMILES: C=Cc1cc(OCC2CO2)c(OCC2CO2)c(OCC2CO2)c1 ; C=Cc1ccc(OCC2(C)COC2)cc1 ; Oc1ccc(I)cc1 ; O=C(O)c1ccc(I)cc1 ; Nc1ccc(I)cc1 ; Sc1ccc(I)cc1]

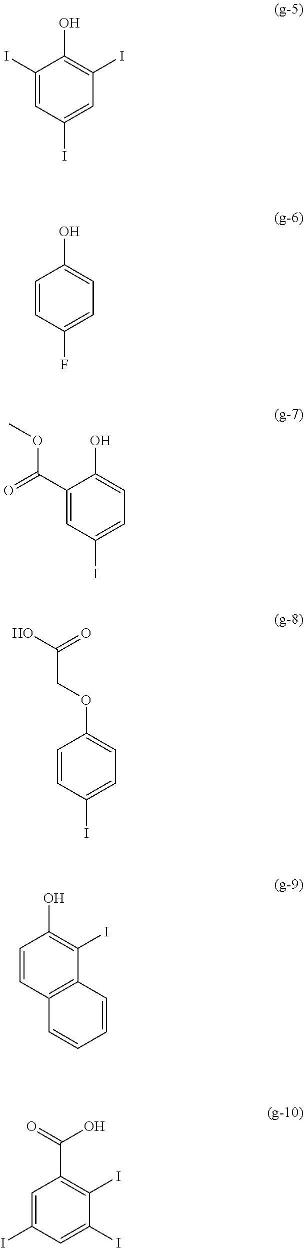

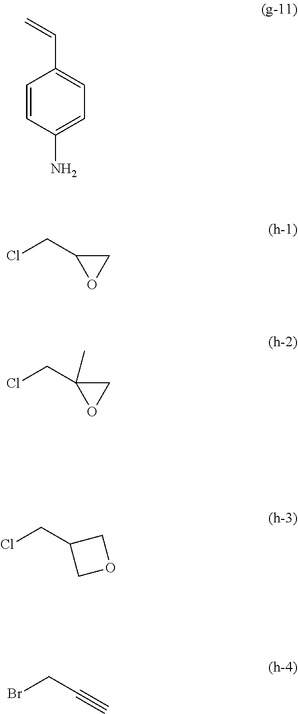

### [Synthesis Example 1-1] (Synthesis of Compound (a-1))

In a reaction vessel, 5.00 g of the compound (f-1), 6.24 g of the compound (g-1), 0.57 g of triethylamine, and 30 g of ethanol were added, and stirred at 60° C. for 6 hours. Then, 2.63 g of the compound (h-1) and 3.92 g of potassium carbonate were added, and stirred at 60° C. for 8 hours. After completion of the reaction, 200 g of ultrapure water was added, affording a precipitate. The precipitate was dissolved in 40 g of methyl ethyl ketone, and precipitated and purified with 5 times amount of heptane to obtain 11 g of a white solid compound (a-1).

### [Synthesis Examples 1-2 to 1-5 and 1-8 to 1-14] (Synthesis of Compounds (a-2) to (a-5) and (a-8) to (a-14))

Compounds (a-2) to (a-5) and (a-8) to (a-14) were synthesized in the same manner as the compound (a-1) except that the compounds [f], [g], and [h] shown in Table 1 were used. The yield (%) of the obtained compound [a] is also shown in Table 1.

### [Synthesis Example 1-6] (Synthesis of Compound (a-6))

In a reaction vessel, 5.00 g of the compound (f-1), 6.22 g of the compound (g-3), and 30 g of ethanol were added, and stirred at 60° C. for 6 hours. Then, 2.63 g of the compound (h-1) and 3.92 g of potassium carbonate were added, and stirred at 60° C. for 8 hours. After completion of the reaction, 200 g of ultrapure water was added, affording a precipitate. The precipitate was dissolved in 40 g of methyl ethyl ketone, and precipitated and purified with 5 times amount of heptane to obtain 9.7 g of a white solid compound (a-6).

### [Synthesis Example 1-7] (Synthesis of Compound (a-7))

In a reaction vessel, 5.00 g of the compound (f-1), 6.70 g of the compound (g-4), 2.87 g of triethylamine, and 30 g of ethanol were added, and stirred at 60° C. for 6 hours. Then, 2.63 g of the compound (h-1) and 3.92 g of potassium carbonate were added, and stirred at 60° C. for 8 hours. After completion of the reaction, 200 g of ultrapure water was added, affording a precipitate. The precipitate was dissolved in 40 g of methyl ethyl ketone, and precipitated and purified with 5 times amount of heptane to obtain 9.7 g of a white solid compound (a-7).

### [Synthesis Examples 1-15 to 1-23] (Synthesis of Compounds (a-15) to (a-23) )

Compounds (a-15) to (a-23) were synthesized in the same manner as the compound (a-1) except that the compounds [f], [g], and [h] shown in Table 1 were used. The yield (%) of the obtained compound [a] is also shown in Table 1.

TABLE 1

| | | Compound | | Compound | | Compound | | |
|---|---|---|---|---|---|---|---|---|
| | | [f] | | [g] | | [h] | | |
| | Compound | Mono- | Molar | Mono- | Molar | Mono- | Molar | Yield |
| | [a] | mer | ratio | mer | ratio | mer | ratio | (%) |
| Synthesis | a-1 | f-1 | 0.1 | g-1 | 0.1 | h-1 | 0.3 | 85 |
| Example 1 | | | | | | | | |
| Synthesis | a-2 | f-1 | 0.1 | g-1 | 0.1 | h-2 | 0.3 | 77 |
| Example 2 | | | | | | | | |
| Synthesis | a-3 | f-1 | 0.1 | g-1 | 0.1 | h-3 | 0.3 | 78 |
| Example 3 | | | | | | | | |
| Synthesis | a-4 | f-1 | 0.1 | g-1 | 0.1 | h-4 | 0.3 | 81 |
| Example 4 | | | | | | | | |
| Synthesis | a-5 | f-1 | 0.1 | g-2 | 0.1 | h-1 | 0.3 | 83 |
| Example 5 | | | | | | | | |
| Synthesis | a-6 | f-1 | 0.1 | g-3 | 0.1 | h-1 | 0.3 | 76 |
| Example 6 | | | | | | | | |
| Synthesis | a-7 | f-1 | 0.1 | g-4 | 0.1 | h-1 | 0.3 | 73 |
| Example 7 | | | | | | | | |
| Synthesis | a-8 | f-1 | 0.1 | g-5 | 0.1 | h-1 | 0.3 | 81 |
| Example 8 | | | | | | | | |
| Synthesis | a-9 | f-1 | 0.1 | g-5 | 0.1 | h-1 | 0.3 | 82 |
| Example 9 | | | | | | | | |
| Synthesis | a-10 | f-1 | 0.1 | g-5 | 0.1 | h-4 | 0.3 | 80 |
| Example 10 | | | | | | | | |
| Synthesis | a-11 | f-1 | 0.1 | g-6 | 0.1 | h-1 | 0.3 | 75 |
| Example 11 | | | | | | | | |
| Synthesis | a-12 | f-1 | 0.1 | g-7 | 0.1 | h-1 | 0.3 | 71 |
| Example 12 | | | | | | | | |
| Synthesis | a-13 | f-1 | 0.1 | g-8 | 0.1 | h-1 | 0.3 | 74 |
| Example 13 | | | | | | | | |
| Synthesis | a-14 | f-1 | 0.1 | g-9 | 0.1 | h-1 | 0.3 | 83 |
| Example 14 | | | | | | | | |
| Synthesis | a-15 | f-2 | 0.1 | g-1 | 0.1 | h-1 | 0.3 | 78 |
| Example 15 | | | | | | | | |
| Synthesis | a-16 | f-3 | 0.1 | g-1 | 0.1 | h-1 | 0.3 | 79 |
| Example 16 | | | | | | | | |
| Synthesis | a-17 | f-3 | 0.1 | g-10 | 0.1 | h-1 | 0.3 | 82 |
| Example 17 | | | | | | | | |
| Synthesis | a-18 | f-3 | 0.1 | g-10 | 0.1 | h-1 | 0.3 | 81 |
| Example 18 | | | | | | | | |
| Synthesis | a-19 | f-3 | 0.1 | g-10 | 0.1 | h-4 | 0.3 | 74 |
| Example 19 | | | | | | | | |
| Synthesis | a-20 | f-4 | 0.1 | g-11 | 0.1 | h-1 | 0.3 | 78 |
| Example 20 | | | | | | | | |
| Synthesis | a-21 | f-5 | 0.1 | g-1 | 0.1 | h-1 | 0.3 | 83 |
| Example 21 | | | | | | | | |
| Synthesis | a-22 | f-6 | 0.1 | g-1 | 0.1 | h-1 | 0.3 | 84 |
| Example 22 | | | | | | | | |
| Synthesis | a-23 | f-7 | 0.1 | g-1 | 0.1 | h-1 | 0.3 | 76 |
| Example 23 | | | | | | | | |

The following compounds (b-1) to (b-4), the following compounds (c-1) to (c-5), the following compounds (d-1) to (d-6), and the following compounds (e-1) to (e-2) as monomers were used for synthesis of the polymer [A].

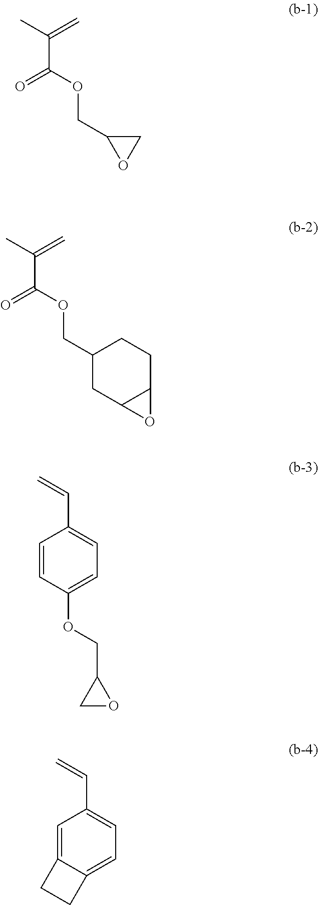

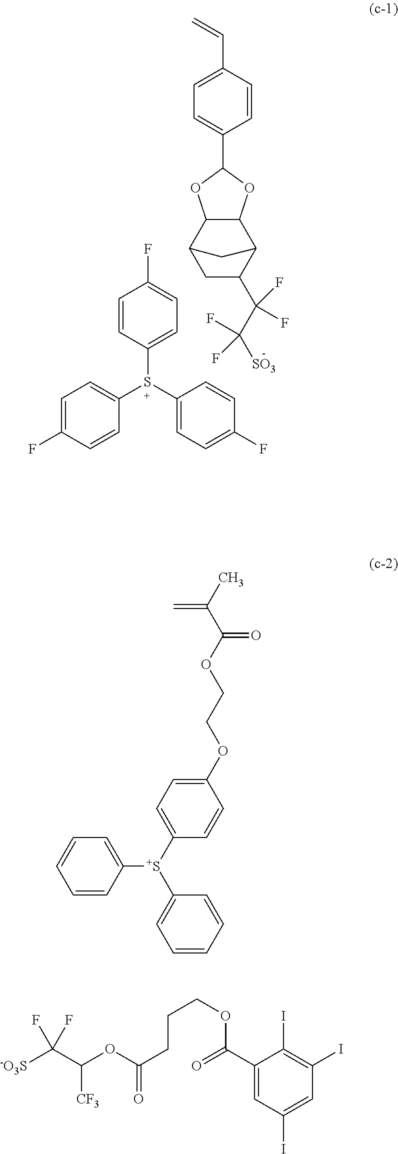

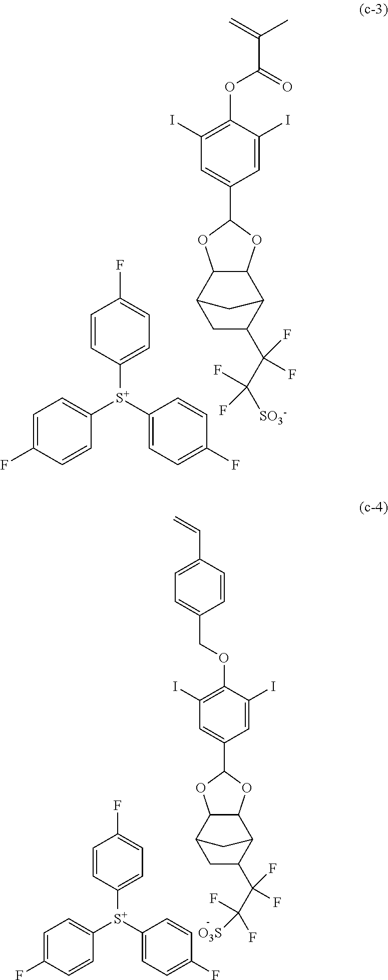

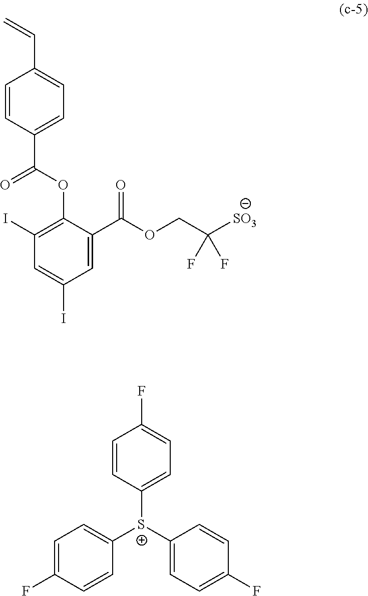

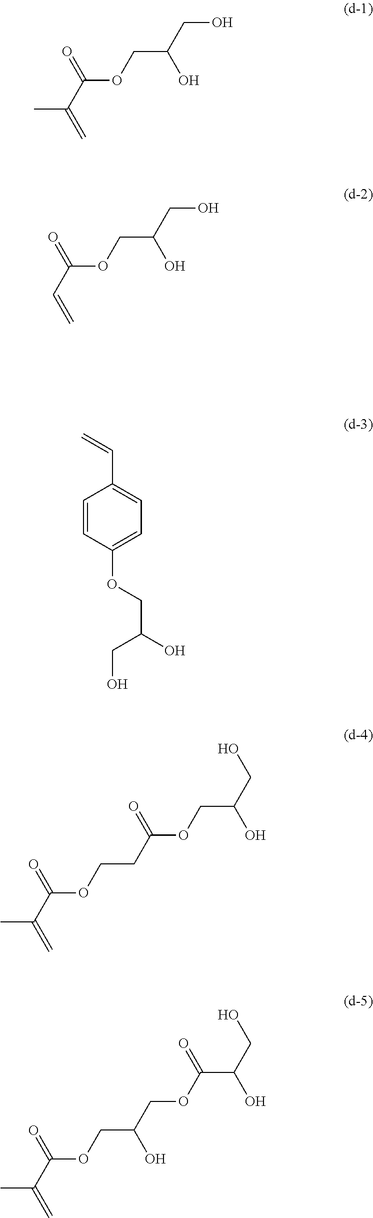

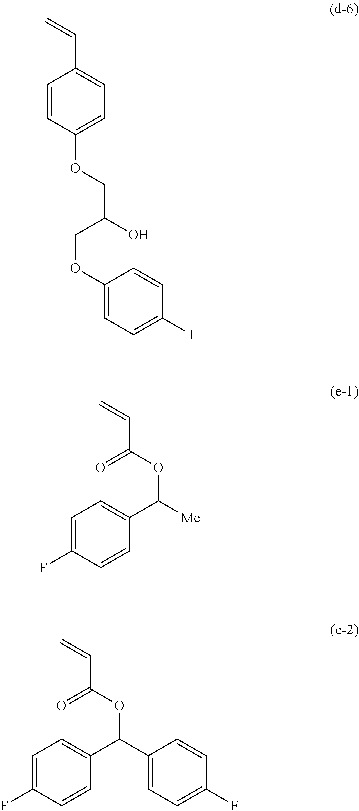 [SMILES: C=Cc1ccc(OCC(O)COc2ccc(I)cc2)cc1 ; C=CC(=O)OC(C)c1ccc(F)cc1 ; C=CC(=O)OC(c1ccc(F)cc1)c1ccc(F)cc1]

### [Synthesis Example 2-1] (Synthesis of Polymer (A-1))

Into a reaction vessel, 6 g of 2-methoxy-1-methylethyl acetate was charged and kept at 80° C., and a mixed liquid of 6.00 g of the compound (a-1), 0.62 g of dimethyl-2,2-azobis(2-methylpropionate), and 12.00 g of 2-methoxy-1-methylethyl acetate was added dropwise from a feeder over 3 hours. After the completion of the dropwise addition, the mixture was stirred at 80° C. for 3 hours. The obtained polymerization liquid was precipitated and purified with 5 times amount of methanol to obtain 5.2 g of a white solid polymer (A-1).

### [Synthesis Examples 2-2 to 2-23] (Synthesis of Polymers (A-2) to (A-23))

Polymers (A-2) to (A-23) were synthesized in the same manner as the polymer (A-1) except that the compound [a] shown in Table 2 was used. The Mw, Mn, and PDI of the obtained polymer [A] are also shown in Table 2. In Table 2, “-” indicates that the corresponding component was not used. The same applies to the following tables.

### [Synthesis Example 2-24] (Synthesis of Polymer (A-24))

Into a reaction vessel, 6 g of 2-methoxy-1-methylethyl acetate was charged and kept at 80° C., and a mixed liquid of 4.96 g of the compound (a-1), 1.04 g of the compound (b-1), 0.62 g of dimethyl-2,2-azobis(2-methylpropionate), and 12.00 g of 2-methoxy-1-methylethyl acetate was added dropwise from a feeder over 3 hours. After the completion of the dropwise addition, the mixture was stirred at 80° C. for 3 hours. The obtained polymerization liquid was precipitated and purified with 5 times amount of methanol to obtain 5.2 g of a white solid polymer (A-24).

### [Synthesis Examples 2-25 to 2-27] (Synthesis of Polymers (A-25) to (A-27))

Polymers (A-25) to (A-27) were synthesized in the same manner as the polymer (A-24) except that the compound [a] and the compound [b] shown in Table 2 were used. The Mw, Mn, and PDI of the obtained polymer [A] are also shown in Table 2.

### [Synthesis Example 2-28] (Synthesis of Polymer (A-28))

Into a reaction vessel, 6 g of 2-methoxy-1-methylethyl acetate was charged and kept at 80° C., and a mixed liquid of 4.26 g of the compound (a-1), 0.67 g of the compound (b-1), 1.07 g of the compound (c-1), 0.72 g of dimethyl-2,2-azobis(2-methylpropionate), and 12.00 g of 2-methoxy-1-methylethyl acetate was added dropwise from a feeder over 3 hours. After the completion of the dropwise addition, the mixture was stirred at 80° C. for 3 hours. The obtained polymerization liquid was precipitated and purified with 5 times amount of methanol to obtain 5.1 g of a white solid polymer (A-28).

### [Synthesis Examples 2-29 to 2-34] (Synthesis of Polymers (A-29) to (A-34))

Polymers (A-29) to (A-34) were synthesized in the same manner as the polymer (A-28) except that the compound [a], the compound [b], and the compound [c] shown in Table 2 were used. The Mw, Mn, and PDI of the obtained polymer [A] are also shown in Table 2.

### [Synthesis Example 2-35] (Synthesis of Polymer (A-35))

Into a reaction vessel, 6 g of 2-methoxy-1-methylethyl acetate was charged and kept at 80° C., and a mixed liquid of 3.85 g of the compound (a-1), 0.72 g of the compound (b-1), 1.17 g of the compound (c-1), 0.27 g of the compound (d-1), 0.72 g of dimethyl-2,2-azobis(2-methylpropionate), and 12.00 g of 2-methoxy-1-methylethyl acetate was added dropwise from a feeder over 3 hours. After the completion of the dropwise addition, the mixture was stirred at 80° C. for 3 hours. The obtained polymerization liquid was precipitated and purified with 5 times amount of methanol to obtain 5.0 g of a white solid polymer (A-35).

### [Synthesis Examples 2-36 to 2-41] (Synthesis of Polymers (A-36) to (A-41))

Polymers (A-36) to (A-41) were synthesized in the same manner as the polymer (A-35) except that the compound [a], the compound [b], the compound [c], and the compound [d] shown in Table 2 were used. The Mw, Mn, and PDI of the obtained polymer [A] are also shown in Table 2.

### [Synthesis Example 2-42] (Synthesis of Polymer (A-42))

Into a reaction vessel, 6 g of 2-methoxy-1-methylethyl acetate was charged and kept at 80° C., and a mixed liquid of 1.95 g of the compound (a-1), 0.92 g of the compound (b-1), 1.48 g of the compound (c-1), 0.35 g of the compound (d-1), 1.25 g of the compound (e-1), 0.99 g of dimethyl-2,2-azobis(2-methylpropionate), and 12.00 g of 2-methoxy-1-methylethyl acetate was added dropwise from a feeder over 3 hours. After the completion of the dropwise addition, the mixture was stirred at 80° C. for 3 hours. The obtained polymerization liquid was precipitated and purified with 5 times amount of methanol to obtain 5.2 g of a white solid polymer (A-42).

### [Synthesis Examples 2-43 to 2-44] (Synthesis of Polymers (A-43) to (A-44))

Polymers (A-43) to (A-44) were synthesized in the same manner as the polymer (A-42) except that the compound [a], the compound [b], the compound [c], the compound [d], and the compound [e] shown in Table 2 were used. The Mw, Mn, and PDI of the obtained polymer [A] are also shown in Table 2.

### Synthesis of Polymer [x]

### [Comparative Synthesis Example 1] (Synthesis of Polymer (x-1))

Into a reaction vessel, 3 g of dimethylacetamide was charged and kept at 80° C., and a mixed liquid of 3.00 g of 4-hydroxystyrene, 0.31 g of dimethyl-2,2-azobis(2-methylpropionate), and 6.00 g of dimethylacetamide was added dropwise from a feeder for 3 hours. After the completion of the dropwise addition, the mixture was stirred at 80° C. for 3 hours. The obtained polymerization liquid was precipitated and purified with 10 times amount of methanol to obtain 2.50 g (yield: 75%) of a polymer (x-1) represented by formula as a white solid. The obtained polymer (x-1) had an Mw of 4500, an Mn of 2800, and a PDI of 1.6.

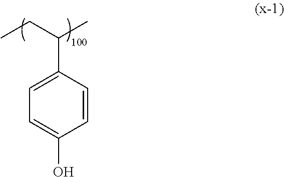

TABLE 2

| | | Compound[a] | | Compound[b] | | Compound[c] | | Compound[d] | | Compound[e] | | | | |
|---|---|---|---|---|---|---|---|---|---|---|---|---|---|---|
| | Polymer | Mono- | | Mono- | | Mono- | | Mono- | | Mono- | | | | |
| | [A] | mer | mol % | mer | mol % | mer | mol % | mer | mol % | mer | mol % | Mw | Mn | PDI |
| Synthesis | A-1 | a-1 | 100 | — | — | — | — | — | — | — | — | 6500 | 3800 | 1.7 |
| Example 2-1 | | | | | | | | | | | | | | |
| Synthesis | A-2 | a-2 | 100 | — | — | — | — | — | — | — | — | 6700 | 3900 | 1.7 |
| Example 2-2 | | | | | | | | | | | | | | |
| Synthesis | A-3 | a-3 | 100 | — | — | — | — | — | — | — | — | 6400 | 3700 | 1.7 |
| Example 2-3 | | | | | | | | | | | | | | |
| Synthesis | A-4 | a-4 | 100 | — | — | — | — | — | — | — | — | 6000 | 3500 | 1.7 |
| Example 2-4 | | | | | | | | | | | | | | |
| Synthesis | A-5 | a-5 | 100 | — | — | — | — | — | — | — | — | 6300 | 3900 | 1.6 |
| Example 2-5 | | | | | | | | | | | | | | |
| Synthesis | A-6 | a-6 | 100 | — | — | — | — | — | — | — | — | 6200 | 3800 | 1.6 |
| Example 2-6 | | | | | | | | | | | | | | |
| Synthesis | A-7 | a-7 | 100 | — | — | — | — | — | — | — | — | 6600 | 3800 | 1.7 |
| Example 2-7 | | | | | | | | | | | | | | |
| Synthesis | A-8 | a-8 | 100 | — | — | — | — | — | — | — | — | 6100 | 3500 | 1.7 |
| Example 2-8 | | | | | | | | | | | | | | |
| Synthesis | A-9 | a-9 | 100 | — | — | — | — | — | — | — | — | 6700 | 3900 | 1.7 |
| Example 2-9 | | | | | | | | | | | | | | |
| Synthesis | A-10 | a-10 | 100 | — | — | — | — | — | — | — | — | 6300 | 3700 | 1.7 |
| Example 2-10 | | | | | | | | | | | | | | |
| Synthesis | A-11 | a-11 | 100 | — | — | — | — | — | — | — | — | 6100 | 3800 | 1.6 |
| Example 2-11 | | | | | | | | | | | | | | |
| Synthesis | A-12 | a-12 | 100 | — | — | — | — | — | — | — | — | 5900 | 3600 | 1.6 |
| Example 2-12 | | | | | | | | | | | | | | |
| Synthesis | A-13 | a-13 | 100 | — | — | — | — | — | — | — | — | 6400 | 3700 | 1.7 |
| Example 2-13 | | | | | | | | | | | | | | |
| Synthesis | A-14 | a-14 | 100 | — | — | — | — | — | — | — | — | 6500 | 4000 | 1.6 |
| Example 2-14 | | | | | | | | | | | | | | |
| Synthesis | A-15 | a-15 | 100 | — | — | — | — | — | — | — | — | 6400 | 4000 | 1.6 |
| Example 2-15 | | | | | | | | | | | | | | |
| Synthesis | A-16 | a-16 | 100 | — | — | — | — | — | — | — | — | 6500 | 3800 | 1.7 |
| Example 2-16 | | | | | | | | | | | | | | |
| Synthesis | A-17 | a-17 | 100 | — | — | — | — | — | — | — | — | 6700 | 4100 | 1.6 |
| Example 2-17 | | | | | | | | | | | | | | |
| Synthesis | A-18 | a-18 | 100 | — | — | — | — | — | — | — | — | 6400 | 4000 | 1.6 |
| Example 2-18 | | | | | | | | | | | | | | |
| Synthesis | A-19 | a-19 | 100 | — | — | — | — | — | — | — | — | 6000 | 3500 | 1.7 |
| Example 2-19 | | | | | | | | | | | | | | |
| Synthesis | A-20 | a-20 | 100 | — | — | — | — | — | — | — | — | 6300 | 3900 | 1.6 |
| Example 2-20 | | | | | | | | | | | | | | |
| Synthesis | A-21 | a-21 | 100 | — | — | — | — | — | — | — | — | 6200 | 3800 | 1.6 |
| Example 2-21 | | | | | | | | | | | | | | |
| Synthesis | A-22 | a-22 | 100 | — | — | — | — | — | — | — | — | 6600 | 3800 | 1.7 |
| Example 2-22 | | | | | | | | | | | | | | |
| Synthesis | A-23 | a-23 | 100 | — | — | — | — | — | — | — | — | 6100 | 3500 | 1.7 |
| Example 2-23 | | | | | | | | | | | | | | |
| Synthesis | A-24 | a-1 | 60 | b-1 | 40 | — | — | — | — | — | — | 6700 | 4100 | 1.6 |
| Example 2-24 | | | | | | | | | | | | | | |
| Synthesis | A-25 | a-1 | 60 | b-2 | 40 | — | — | — | — | — | — | 6300 | 3900 | 1.6 |
| Example 2-25 | | | | | | | | | | | | | | |
| Synthesis | A-26 | a-1 | 60 | b-3 | 40 | — | — | — | — | — | — | 6100 | 3500 | 1.7 |
| Example 2-26 | | | | | | | | | | | | | | |
| Synthesis | A-27 | a-1 | 60 | b-4 | 40 | — | — | — | — | — | — | 5900 | 3400 | 1.7 |
| Example 2-27 | | | | | | | | | | | | | | |
| Synthesis | A-28 | a-1 | 60 | b-1 | 30 | c-1 | 10 | — | — | — | — | 6400 | 3700 | 1.7 |
| Example 2-28 | | | | | | | | | | | | | | |
| Synthesis | A-29 | a-1 | 30 | b-1 | 60 | c-1 | 10 | — | — | — | — | 6500 | 3800 | 1.7 |
| Example 2-29 | | | | | | | | | | | | | | |
| Synthesis | A-30 | a-1 | 40 | b-1 | 40 | c-1 | 20 | — | — | — | — | 6400 | 4000 | 1.6 |
| Example 2-30 | | | | | | | | | | | | | | |
| Synthesis | A-31 | a-1 | 60 | b-1 | 30 | c-2 | 10 | — | — | — | — | 6300 | 3900 | 1.6 |
| Example 2-31 | | | | | | | | | | | | | | |
| Synthesis | A-32 | a-1 | 60 | b-1 | 30 | c-3 | 10 | — | — | — | — | 6200 | 3600 | 1.7 |
| Example 2-32 | | | | | | | | | | | | | | |
| Synthesis | A-33 | a-1 | 60 | b-1 | 30 | c-4 | 10 | — | — | — | — | 6600 | 4100 | 1.6 |
| Example 2-33 | | | | | | | | | | | | | | |
| Synthesis | A-34 | a-1 | 60 | b-1 | 30 | c-5 | 10 | — | — | — | — | 6100 | 3500 | 1.7 |
| Example 2-34 | | | | | | | | | | | | | | |
| Synthesis | A-35 | a-1 | 50 | b-1 | 30 | c-1 | 10 | d-1 | 10 | — | — | 6700 | 3900 | 1.7 |
| Example 2-35 | | | | | | | | | | | | | | |
| Synthesis | A-36 | a-1 | 20 | b-1 | 30 | c-1 | 10 | d-1 | 40 | — | — | 6300 | 3700 | 1.7 |
| Example 2-36 | | | | | | | | | | | | | | |
| Synthesis | A-37 | a-1 | 50 | b-1 | 30 | c-1 | 10 | d-2 | 10 | — | — | 6100 | 3500 | 1.7 |
| Example 2-37 | | | | | | | | | | | | | | |
| Synthesis | A-38 | a-1 | 50 | b-1 | 30 | c-1 | 10 | d-3 | 10 | — | — | 6500 | 4000 | 1.6 |
| Example 2-38 | | | | | | | | | | | | | | |
| Synthesis | A-39 | a-1 | 50 | b-1 | 30 | c-1 | 10 | d-4 | 10 | — | — | 6400 | 3700 | 1.7 |
| Example 2-39 | | | | | | | | | | | | | | |
| Synthesis | A-40 | a-1 | 50 | b-1 | 30 | c-1 | 10 | d-5 | 10 | — | — | 6500 | 3800 | 1.7 |
| Example 2-40 | | | | | | | | | | | | | | |
| Synthesis | A-41 | a-1 | 50 | b-1 | 30 | c-1 | 10 | d-6 | 10 | — | — | 6700 | 3900 | 1.7 |
| Example 2-41 | | | | | | | | | | | | | | |
| Synthesis | A-42 | a-1 | 20 | b-1 | 30 | c-1 | 10 | d-1 | 10 | e-1 | 30 | 6400 | 3700 | 1.7 |
| Example 2-42 | | | | | | | | | | | | | | |
| Synthesis | A-43 | a-1 | 40 | b-1 | 30 | c-1 | 10 | d-1 | 10 | e-1 | 10 | 6300 | 3900 | 1.6 |
| Example 2-43 | | | | | | | | | | | | | | |
| Synthesis | A-44 | a-1 | 20 | b-1 | 30 | c-1 | 10 | d-1 | 10 | e-2 | 30 | 6200 | 3600 | 1.7 |
| Example 2-44 | | | | | | | | | | | | | | |

### <Preparation of Composition>

The polymer [A], the polymer [E], the solvent [B], the acid generator [C], the cross linking agent [D], and the polymer [X] used for the preparation of compositions are shown below.

### [Polymer [A]]

A-1 to A-44: Polymers (A-1) to (A-44) synthesized above

[Polymer [x]]

x-1: Polymer (x-1) synthesized above

### [Solvent [B]]

B-1: Propylene glycol monomethyl ether acetate

B-2: Cyclohexanone

### [Acid Generator [C]]

C-1: Compound represented by formula (C-1)

C-2: Compound represented by formula (C-2)

C-3: Compound represented by formula (C-3)

C-4: Compound represented by formula (C-4)

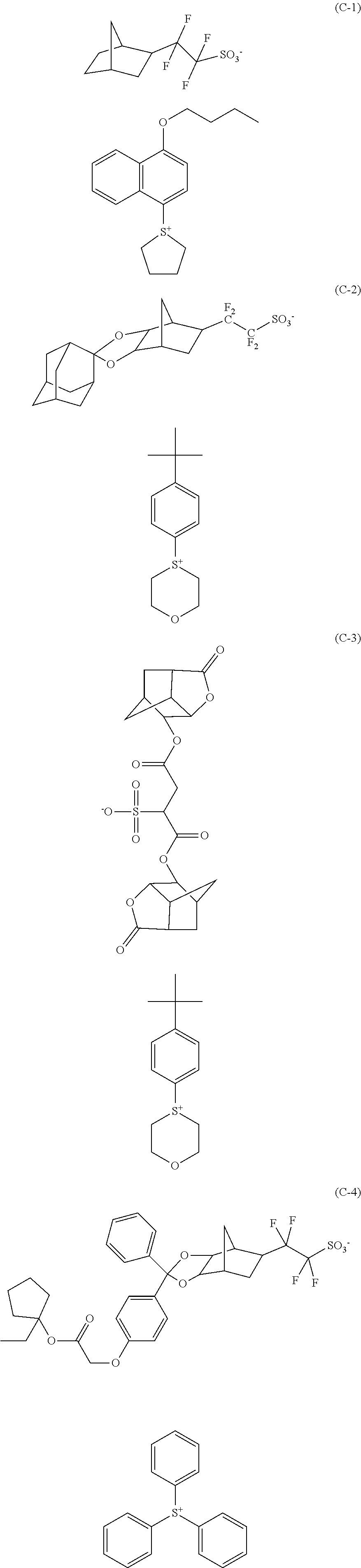

### [Crosslinking Agent [D]]

D-1: Compound represented by formula (D-1)

D-2: Compound represented by formula (D-2)

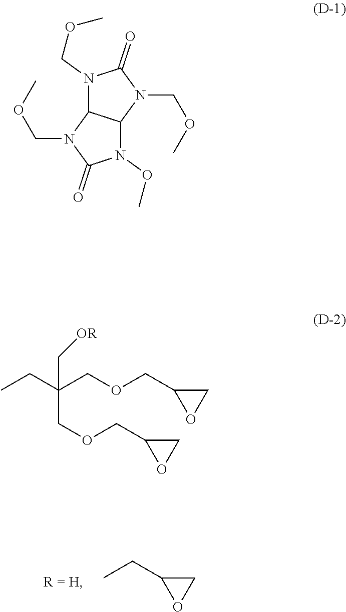

### Example 1-1

In 7900 parts by mass of (B-1) and 2000 parts by mass of (B-2) as the solvent [B], 50 parts by mass of (A-1) as the polymer [A] was dissolved. The resulting solution was filtered through a polytetrafluoroethylene (PTFE) membrane filter having a pore size of 0.45 μm to prepare composition (J-1).

### Examples 1-2 to 1-52 and Comparative Example 1-1

Compositions (J-2) to (J-52) and (CJ-1) were prepared in the same manner as in Example 1-1 except that the components of the types and contents shown in the following Table 3 were used. “-” in Table 3 indicates that the corresponding component was not used.

TABLE 3

| | | Polymer | | Solvent | | Acid generator | | Crosslinking | | Polymer | |
|---|---|---|---|---|---|---|---|---|---|---|---|
| | | [A] | | [B] | | [C] | | agent [D] | | [x] | |
| | | | Content | | Content | | Content | | Content | | Content |
| | | | (Parts | | (Parts | | (Parts | | (Parts | | (Parts |
| | Composition | Type | by mass) | Type | by mass) | Type | by mass) | Type | by mass) | Type | by mass) |
| Example 1-1 | J-1 | A-1 | 50 | B-1/B-2 | 7900/2000 | — | — | — | — | — | — |
| Example 1-2 | J-2 | A-1 | 25 | B-1/B-2 | 7900/2000 | — | — | — | — | — | — |
| Example 1-3 | J-3 | A-1 | 25 | B-1/B-2 | 7900/2000 | C-1 | 5 | — | — | — | — |
| Example 1-4 | J-4 | A-1 | 25 | B-1/B-2 | 7900/2000 | C-2 | 5 | — | — | — | — |
| Example 1-5 | J-5 | A-1 | 25 | B-1/B-2 | 7900/2000 | C-3 | 5 | — | — | — | — |
| Example 1-6 | J-6 | A-1 | 25 | B-1/B-2 | 7900/2000 | C-4 | 5 | — | — | — | — |
| Example 1-7 | J-7 | A-2 | 25 | B-1/B-2 | 7900/2000 | C-1 | 5 | — | — | — | — |
| Example 1-8 | J-8 | A-3 | 25 | B-1/B-2 | 7900/2000 | C-1 | 5 | — | — | — | — |
| Example 1-9 | J-9 | A-4 | 25 | B-1/B-2 | 7900/2000 | C-1 | 5 | — | — | — | — |
| Example 1-10 | J-10 | A-5 | 25 | B-1/B-2 | 7900/2000 | C-1 | 5 | — | — | — | — |
| Example 1-11 | J-11 | A-6 | 25 | B-1/B-2 | 7900/2000 | C-1 | 5 | — | — | — | — |
| Example 1-12 | J-12 | A-7 | 25 | B-1/B-2 | 7900/2000 | C-1 | 5 | — | — | — | — |
| Example 1-13 | J-13 | A-8 | 25 | B-1/B-2 | 7900/2000 | C-1 | 5 | — | — | — | — |
| Example 1-14 | J-14 | A-9 | 25 | B-1/B-2 | 7900/2000 | C-1 | 5 | — | — | — | — |
| Example 1-15 | J-15 | A-10 | 25 | B-1/B-2 | 7900/2000 | C-1 | 5 | — | — | — | — |
| Example 1-16 | J-16 | A-11 | 25 | B-1/B-2 | 7900/2000 | C-1 | 5 | — | — | — | — |
| Example 1-17 | J-17 | A-12 | 25 | B-1/B-2 | 7900/2000 | C-1 | 5 | — | — | — | — |
| Example 1-18 | J-18 | A-13 | 25 | B-1/B-2 | 7900/2000 | C-1 | 5 | — | — | — | — |
| Example 1-19 | J-19 | A-14 | 25 | B-1/B-2 | 7900/2000 | C-1 | 5 | — | — | — | — |
| Example 1-20 | J-20 | A-15 | 25 | B-1/B-2 | 7900/2000 | C-1 | 5 | — | — | — | — |
| Example 1-21 | J-21 | A-16 | 25 | B-1/B-2 | 7900/2000 | C-1 | 5 | — | — | — | — |
| Example 1-22 | J-22 | A-17 | 25 | B-1/B-2 | 7900/2000 | C-1 | 5 | — | — | — | — |
| Example 1-23 | J-23 | A-18 | 25 | B-1/B-2 | 7900/2000 | C-1 | 5 | — | — | — | — |
| Example 1-24 | J-24 | A-19 | 25 | B-1/B-2 | 7900/2000 | C-1 | 5 | — | — | — | — |
| Example 1-25 | J-25 | A-20 | 25 | B-1/B-2 | 7900/2000 | C-1 | 5 | — | — | — | — |
| Example 1-26 | J-26 | A-21 | 25 | B-1/B-2 | 7900/2000 | C-1 | 5 | — | — | — | — |
| Example 1-27 | J-27 | A-22 | 25 | B-1/B-2 | 7900/2000 | C-1 | 5 | — | — | — | — |
| Example 1-28 | J-28 | A-23 | 25 | B-1/B-2 | 7900/2000 | C-1 | 5 | — | — | — | — |
| Example 1-29 | J-29 | A-24 | 25 | B-1/B-2 | 7900/2000 | C-1 | 5 | — | — | — | — |
| Example 1-30 | J-30 | A-25 | 25 | B-1/B-2 | 7900/2000 | C-1 | 5 | — | — | — | — |
| Example 1-31 | J-31 | A-26 | 25 | B-1/B-2 | 7900/2000 | C-1 | 5 | — | — | — | — |
| Example 1-32 | J-32 | A-27 | 25 | B-1/B-2 | 7900/2000 | C-1 | 5 | — | — | — | — |
| Example 1-33 | J-33 | A-28 | 25 | B-1/B-2 | 7900/2000 | C-1 | 5 | — | — | — | — |
| Example 1-34 | J-34 | A-29 | 25 | B-1/B-2 | 7900/2000 | C-1 | 5 | — | — | — | — |
| Example 1-35 | J-35 | A-30 | 25 | B-1/B-2 | 7900/2000 | C-1 | 5 | — | — | — | — |
| Example 1-36 | J-36 | A-31 | 25 | B-1/B-2 | 7900/2000 | C-1 | 5 | — | — | — | — |
| Example 1-37 | J-37 | A-32 | 25 | B-1/B-2 | 7900/2000 | C-1 | 5 | — | — | — | — |
| Example 1-38 | J-38 | A-33 | 25 | B-1/B-2 | 7900/2000 | C-1 | 5 | — | — | — | — |
| Example 1-39 | J-39 | A-34 | 25 | B-1/B-2 | 7900/2000 | C-1 | 5 | — | — | — | — |
| Example 1-40 | J-40 | A-35 | 25 | B-1/B-2 | 7900/2000 | C-1 | 5 | — | — | — | — |
| Example 1-41 | J-41 | A-36 | 25 | B-1/B-2 | 7900/2000 | C-1 | 5 | — | — | — | — |
| Example 1-42 | J-42 | A-37 | 25 | B-1/B-2 | 7900/2000 | C-1 | 5 | — | — | — | — |
| Example 1-43 | J-43 | A-38 | 25 | B-1/B-2 | 7900/2000 | C-1 | 5 | — | — | — | — |
| Example 1-44 | J-44 | A-39 | 25 | B-1/B-2 | 7900/2000 | C-1 | 5 | — | — | — | — |
| Example 1-45 | J-45 | A-40 | 25 | B-1/B-2 | 7900/2000 | C-1 | 5 | — | — | — | — |
| Example 1-46 | J-46 | A-41 | 25 | B-1/B-2 | 7900/2000 | C-1 | 5 | — | — | — | — |
| Example 1-47 | J-47 | A-42 | 25 | B-1/B-2 | 7900/2000 | C-1 | 5 | — | — | — | — |
| Example 1-48 | J-48 | A-43 | 25 | B-1/B-2 | 7900/2000 | C-1 | 5 | — | — | — | — |
| Example 1-49 | J-49 | A-44 | 25 | B-1/B-2 | 7900/2000 | C-1 | 5 | — | — | — | — |
| Example 1-51 | J-51 | A-1 | 25 | B-1/B-2 | 7900/2000 | C-1 | 5 | D-1 | 5 | — | — |
| Example 1-52 | J-52 | A-1 | 25 | B-1/B-2 | 7900/2000 | C-1 | 5 | D-2 | 5 | — | — |
| Comparative | CJ-1 | — | — | B-1/B-2 | 7900/2000 | — | — | — | — | x-1 | 25 |
| Example 1-1 | | | | | | | | | | | |

### <Evaluation>

Using the compositions prepared as described above, the solvent resistance and the resist pattern rectangularity due to EUV exposure were evaluated by the following methods. The evaluation results are shown in Table 4.

### [Solvent Resistance]

A composition prepared above was applied to a 12-inch silicon wafer by spin coating using a spin coater (“CLEAN TRACK ACT 12” available from Tokyo Electron Limited). Next, the resultant was heated at 250° C. for 60 seconds in the air atmosphere, and then cooled at 23° C. for 60 seconds to form a resist underlayer film having an average thickness of 5 nm, thereby obtaining a substrate with a resist underlayer film in which a resist underlayer film was formed on the substrate. The obtained substrate with a resist underlayer film was immersed in cyclohexanone (23° C.) for 1 minute. The average film thickness before and after the immersion was measured. Where the average thickness of the resist underlayer film before the immersion was X0 and the average thickness of the resist underlayer film after the immersion was X, the absolute value of the numerical value obtained by {(X−X0)/X0}×100 was calculated and taken as the film thickness change rate (%). The solvent resistance was evaluated as “A” (good) when the film thickness change rate was less than 1%, “B” (slightly good) when the film thickness change rate was 1% or more and less than 10%, and “C” (poor) when the film thickness change rate was 10% or more.

### <Preparation of Resist Composition>

A resist composition (R-1) was obtained by mixing 100 parts by mass of a polymer having a structural unit (1) derived from 4-hydroxystyrene, a structural unit (2) derived from styrene, and a structural unit (3) derived from 4-t-butoxystyrene (content ratio of each structural unit: (1)/(2)/(3)=65/5/30 (mol %)), 1.0 part by mass of triphenylsulfonium trifluoromethanesulfonate as a radiation-sensitive acid generator, and 4,400 parts by mass of ethyl lactate and 1,900 parts by mass of propylene glycol monomethyl ether acetate each as a solvent, and filtering the obtained solution through a filter having a pore size of 0.2 μm.

### [Resist Pattern Rectangularity (EUV Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Ltd.), and thereafter heating was conducted at 250° C. for 60 sec to form an organic underlayer film having an average thickness of 100 nm. To the organic underlayer film was applied a composition for forming a silicon-containing film (“NFC SOG080” manufactured by JSR Corporation), heated at 220° C. for 60 sec, and then cooled at 23° C. for 30 sec. Thus, a silicon-containing film having an average thickness of 20 nm was formed. The composition prepared as described above was applied to the silicon-containing film formed as described above to form a resist underlayer film. The resist underlayer film formed as described above was heated at 250° C. for 90 seconds, and then cooled at 23° C. for 30 seconds, affording a resist underlayer film having an average thickness of 5 nm. To the resist underlayer film formed as described above was applied a resist composition (R-1), heated at 130° C. for 60 sec, and then cooled at 23° C. for 30 sec. Thus, a resist film having an average thickness of 50 nm was formed. Next, the resist film was irradiated with extreme ultraviolet rays using an EUV scanner (“TWINSCAN NXE:3300B”, available from ASML Co. (NA=0.3; Sigma=0.9; quadrupole illumination, with a 1:1 line and space mask having a line width of 16 nm in terms of a dimension on wafer)). After the irradiation with the extreme ultraviolet rays, the substrate was heated at 110° C. for 60 sec, followed by cooling at 23° C. for 60 sec. Thereafter, development was performed by a paddle method using a 2.38% by mass aqueous tetramethylammonium hydroxide solution (20° C. to 25° C.), followed by washing with water and drying, thereby affording a substrate for evaluation on which a resist pattern was formed. A scanning electron microscope (“SU8220” available from Hitachi High-Technologies Corporation) was used for length measurement and observation of the resist pattern of the substrate for evaluation. The resist pattern rectangularity was evaluated as “A” (good) when the cross-sectional shape of the pattern was rectangular, and “B” (poor) when trailing was present in the cross section of the pattern.

TABLE 4

| | | Solvent | Resist pattern |
|---|---|---|---|
| | Composition | resistance | rectangularity |
| Example 2-1 | J-1 | B | A |
| Example 2-2 | J-2 | B | A |
| Example 2-3 | J-3 | A | A |
| Example 2-4 | J-4 | A | A |
| Example 2-5 | J-5 | A | A |
| Example 2-6 | J-6 | A | A |
| Example 2-7 | J-7 | A | A |
| Example 2-8 | J-8 | A | A |
| Example 2-9 | J-9 | A | A |
| Example 2-10 | J-10 | A | A |
| Example 2-11 | J-11 | A | A |
| Example 2-12 | J-12 | A | A |
| Example 2-13 | J-13 | A | A |
| Example 2-14 | J-14 | A | A |
| Example 2-15 | J-15 | A | A |
| Example 2-16 | J-16 | A | A |
| Example 2-17 | J-17 | A | A |
| Example 2-18 | J-18 | A | A |
| Example 2-19 | J-19 | A | A |
| Example 2-20 | J-20 | A | A |
| Example 2-21 | J-21 | A | A |
| Example 2-22 | J-22 | A | A |
| Example 2-23 | J-23 | A | A |
| Example 2-24 | J-24 | A | A |
| Example 2-25 | J-25 | A | A |
| Example 2-26 | J-26 | A | A |
| Example 2-27 | J-27 | A | A |
| Example 2-28 | J-28 | A | A |
| Example 2-29 | J-29 | A | A |
| Example 2-30 | J-30 | A | A |
| Example 2-31 | J-31 | A | A |
| Example 2-32 | J-32 | A | A |
| Example 2-33 | J-33 | A | A |
| Example 2-34 | J-34 | A | A |
| Example 2-35 | J-35 | A | A |
| Example 2-36 | J-36 | A | A |
| Example 2-37 | J-37 | A | A |
| Example 2-38 | J-38 | A | A |
| Example 2-39 | J-39 | A | A |
| Example 2-40 | J-40 | A | A |
| Example 2-41 | J-41 | A | A |
| Example 2-42 | J-42 | A | A |
| Example 2-43 | J-43 | A | A |
| Example 2-44 | J-44 | A | A |
| Example 2-45 | J-45 | A | A |
| Example 2-46 | J-46 | A | A |
| Example 2-47 | J-47 | A | A |
| Example 2-48 | J-48 | A | A |
| Example 2-49 | J-49 | A | A |
| Example 2-51 | J-51 | A | A |
| Example 2-52 | J-52 | A | A |
| Comparative | CJ-1 | C | B |
| Example 2-1 | | | |

### <Evaluation>

Using the compositions prepared as described above, the rectangularity of a resist pattern due to EUV exposure was evaluated by the following method. The evaluation results are given in the following Table 5.

### <Preparation of Resist Composition (R-2)>

The compound (S-1) to be used for the preparation of a resist composition (R-2) was synthesized by the following procedure. In a reaction vessel, 6.5 parts by mass of isopropyltin trichloride was added while stirring 150 mL of a 0.5 N aqueous sodium hydroxide solution, and stirring was carried out for 2 hours. The precipitate formed was collected by filtration, washed twice with 50 parts by mass of water, and then dried, affording a compound (S-1). The compound (S-1) was an oxidized hydroxide product of a hydrolysate of isopropyltin trichloride (the oxidized hydroxide product contained i-PrSnO_{(3/2-x/2)}(OH)ₓ (0<x<3) as a structural unit).

2 parts by mass of the compound (S-1) synthesized above and 98 parts by mass of propylene glycol monoethyl ether were mixed, and the resulting mixture was subjected to removal of residual water with activated 4 Å molecular sieve, and then filtered through a filter having a pore size of 0.2 μm. Thus, a resist composition (R-2) was prepared.

### [Resist Pattern Rectangularity (EUV Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Ltd.), and thereafter heating was conducted at 250° C. for 60 sec to form an organic underlayer film having an average thickness of 100 nm. To the organic underlayer film was applied the composition for forming a resist underlayer film prepared above, heated at 220° C. for 60 sec, and then cooled at 23° C. for 30 sec. Thus, a resist underlayer film having an average thickness of 5 nm was formed. To the resist underlayer film was applied the resist composition (R-2) by the spin coating method using the spin coater described above, and after a lapse of a prescribed time, heated at 90° C. for 60 sec, and then cooled at 23° C. for 30 sec. Thus, a resist film having an average thickness of 35 nm was formed. The resist film was exposed to light using an EUV scanner (“TWINSCAN NXE:3300B”, available from ASML Co. (NA=0.3; Sigma=0.9; quadrupole illumination, with a 1:1 line and space mask having a line width of 16 nm in terms of a dimension on wafer)). After the exposure, the substrate was heated at 110° C. for 60 sec, and subsequently cooled at 23° C. for 60 sec. Thereafter, development was performed by a paddle method using 2-heptanone (20 to 25° C.), and then dried, affording a substrate for evaluation on which a resist pattern was formed. A scanning electron microscope (“CG-6300” available from Hitachi High-Tech Corporation) was used for length measurement and observation of the resist pattern of the substrate for evaluation. The resist pattern rectangularity was evaluated as “A” (good) when the cross-sectional shape of the pattern was rectangular, and “B” (poor) when trailing was present in the cross section of the pattern.

TABLE 5

| | | Resist pattern |
|---|---|---|
| | Composition | rectangularity |
| Example 3-1 | J-1 | A |
| Example 3-2 | J-2 | A |
| Example 3-3 | J-3 | A |
| Example 3-4 | J-4 | A |
| Example 3-5 | J-5 | A |
| Example 3-6 | J-6 | A |
| Example 3-7 | J-7 | A |
| Example 3-8 | J-8 | A |
| Example 3-9 | J-9 | A |
| Example 3-10 | J-10 | A |
| Example 3-11 | J-11 | A |
| Example 3-12 | J-12 | A |
| Example 3-13 | J-13 | A |
| Example 3-14 | J-14 | A |
| Example 3-15 | J-15 | A |
| Example 3-16 | J-16 | A |
| Example 3-17 | J-17 | A |
| Example 3-18 | J-18 | A |
| Example 3-19 | J-19 | A |
| Example 3-20 | J-20 | A |
| Example 3-21 | J-21 | A |
| Example 3-22 | J-22 | A |
| Example 3-23 | J-23 | A |
| Example 3-24 | J-24 | A |
| Example 3-25 | J-25 | A |
| Example 3-26 | J-26 | A |
| Example 3-27 | J-27 | A |
| Example 3-28 | J-28 | A |
| Example 3-29 | J-29 | A |
| Example 3-30 | J-30 | A |
| Example 3-31 | J-31 | A |
| Example 3-32 | J-32 | A |
| Example 3-33 | J-33 | A |
| Example 3-34 | J-34 | A |
| Example 3-35 | J-35 | A |
| Example 3-36 | J-36 | A |
| Example 3-37 | J-37 | A |
| Example 3-38 | J-38 | A |
| Example 3-39 | J-39 | A |
| Example 3-40 | J-40 | A |
| Example 3-41 | J-41 | A |
| Example 3-42 | J-42 | A |
| Example 3-43 | J-43 | A |
| Example 3-44 | J-44 | A |
| Example 3-45 | J-45 | A |
| Example 3-46 | J-46 | A |
| Example 3-47 | J-47 | A |
| Example 3-48 | J-48 | A |
| Example 3-49 | J-49 | A |
| Example 3-51 | J-51 | A |
| Example 3-52 | J-52 | A |
| Comparative | CJ-1 | B |
| Example 3-1 | | |

### Example 3-1

As can be seen from the results in Tables 4 to 5, the resist underlayer films formed from the compositions of Examples were excellent in solvent resistance and resist pattern rectangularity to the resist underlayer films formed from the compositions of Comparative Examples.

According to the composition for forming a resist underlayer film of the present disclosure, it is possible to form a film excellent in solvent resistance and resist pattern rectangularity. According to the method for producing a semiconductor substrate of the present disclosure, it is possible to efficiently produce a semiconductor substrate since a composition for forming a resist underlayer film capable of forming a resist underlayer film excellent in solvent resistance and resist pattern rectangularity is used. Therefore, these can be suitably used for the production of a semiconductor device, etc.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A composition comprising:
a polymer comprising a repeating unit represented by formula (1); and
a solvent, 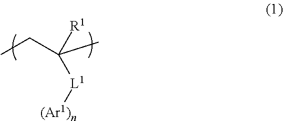
wherein, in the formula (1),
R¹ is a hydrogen atom or a substituted or unsubstituted monovalent hydrocarbon group having 1 to 20 carbon atoms;
L¹ is a (1+n)-valent linking group;
Ar¹ is a monovalent group comprising an aromatic ring having 6 to 20 ring members, the aromatic ring comprising at least one halogen atom;
n is an integer of 1 to 3, when n is 2 or more, a plurality of Ar¹s are same as or different from each other; and
L¹ comprises at least one group (A) selected from the group consisting of a group represented by formula (2-1), a group represented by formula (2-2), a group represented by formula (2-3), a group represented by formula (2-4), a group represented by formula (2-5), a group represented by formula (2-6), a group represented by formula (2-7), and a group represented by formula (2-8), 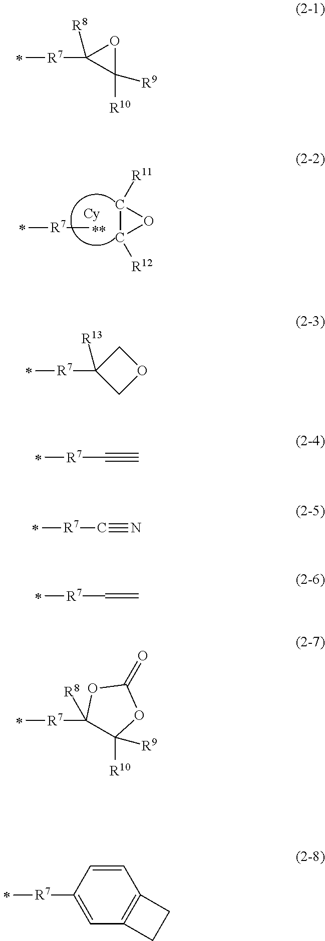
wherein, in the formula (2-1) to (2-8),
R⁷ is independently a divalent organic group having 1 to 20 carbon atoms or a single bond;
R⁸, R⁹, R¹⁰, and R¹³ are each independently a hydrogen atom or a monovalent organic group having 1 to 20 carbon atoms;
Cy is a ring structure having 3 to 20 ring members formed together with the two carbon atoms in the formula (2-2);
R¹¹ is a hydrogen atom, a monovalent organic group having 1 to 20 carbon atoms, or a single bond;
R¹² is a hydrogen atom or a monovalent organic group having 1 to 20 carbon atoms;
** is a bond to an atom constituting Cy, and when R¹¹ is a single bond, R¹¹ bonds to **; and
* is a bond to an atom constituting L¹.

2. The composition according to claim 1, wherein, in the formula (1), L¹ is represented by formula (3-1) or (3-2), 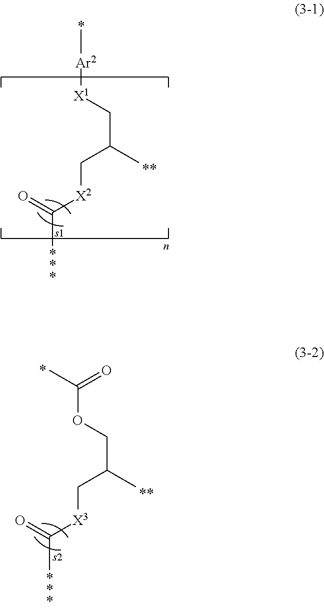
wherein, in the formula (3-1),
Ar² is a (1+n)-valent group comprising an aromatic ring having 6 to 20 ring members;
s1 is 0 or 1; and when there are a plurality of s1s, the plurality of s1s are same as or different from each other;
X¹ and X² are each independently —O—, —NH—, or —S—; when s1 is 1, X² is —O—; and when there are a plurality of X¹s and X²s, the plurality of X¹s and X²s are same as or different from each other;
n is as defined in the formula (1);
wherein, in the formula (3-2),
s2 is 0 or 1;
X³ is —O—, —NH—, or —S—; when s2 is 1, X³ is —O—; and
wherein, in the formulas (3-1) and (3-2), * is a bond to a carbon atom to which R¹ bonds in the formula (1); ** is a bond to the group (A); and *** is a bond to Ar¹ in the formula (1).

3. The composition according to claim 1, wherein a content ratio of the repeating unit represented by the formula (1) in the polymer with respect to all repeating units constituting the polymer is 10 mol % or more.

4. The composition according to claim 1, which is suitable for forming an underlayer film of a resist film to be exposed to extreme ultraviolet rays.

5. A method for producing a semiconductor substrate, comprising:
applying a composition for forming a resist underlayer film directly or indirectly to a substrate to form a resist under layer film;
applying a composition for forming a resist film to the resist underlayer film to form a resist film;
exposing the resist film to radiation; and
developing the exposed resist film,
wherein the composition for forming a resist underlayer film comprises:
a polymer comprising a repeating unit represented by formula (1); and
a solvent, 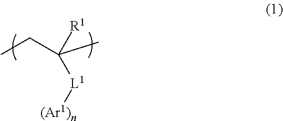
wherein, in the formula (1),
R¹ is a hydrogen atom or a substituted or unsubstituted monovalent hydrocarbon group having 1 to 20 carbon atoms;
L¹ is a (1+n)-valent linking group;
Ar¹ is a monovalent group comprising an aromatic ring having 6 to 20 ring members, the aromatic ring comprising at least one halogen atom;
n is an integer of 1 to 3, when n is 2 or more, a plurality of Ar¹s are same as or different from each other; and
L¹ comprises at least one group (A) selected from the group consisting of a group represented by formula (2-1), a group represented by formula (2-2), a group represented by formula (2-3), a group represented by formula (2-4), a group represented by formula (2-5), a group represented by formula (2-6), a group represented by formula (2-7), and a group represented by formula (2-8), 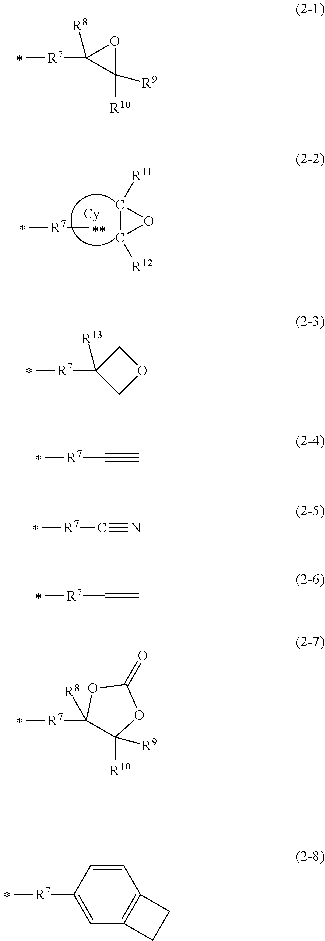
wherein, in the formula (2-1) to (2-8),
R⁷ is independently a divalent organic group having 1 to 20 carbon atoms or a single bond;
R⁸, R⁹, R¹⁰, and R¹³ are each independently a hydrogen atom or a monovalent organic group having 1 to 20 carbon atoms;
Cy is a ring structure having 3 to 20 ring members formed together with the two carbon atoms in the formula (2-2);
R¹¹ is a hydrogen atom, a monovalent organic group having 1 to 20 carbon atoms, or a single bond;
R¹² is a hydrogen atom or a monovalent organic group having 1 to 20 carbon atoms;
** is a bond to an atom constituting Cy, and when R¹¹ is a single bond, R¹¹ bonds to **; and
* is a bond to an atom constituting L¹.

6. The method according to claim 5, wherein the radiation is extreme ultraviolet rays.

7. The method according to claim 5, wherein a film thickness of the resist underlayer film is 20 nm or less.

8. The method according to claim 5, wherein a composition for forming the resist film comprises a metal.
